(19) United States
(12) Patent Application Publication
(10) Pub. No.: US 2026/0187193 A1
(43) Pub. Date: Jul. 2, 2026

(54) DETECTING RF EMISSIONS AND CLASSIFYING RF SOURCES USING SPECTRUM TRANSFORMER MODELS

(71) Applicant: Armada Systems, Inc., San Francisco, CA (US)

(72) Inventor: Pragyana K. Mishra, Seattle, WA (US)

(73) Assignee: Armada Systems, Inc., San Francisco, CA (US)

(21) Appl. No.: 19/006,606

(22) Filed: Dec. 31, 2024

(51) Int. Cl. G06F 18/21; G01R 23/18; G06F 18/25

(52) U.S. Cl. CPC G06F 18/21; G01R 23/18; G06F 18/253; G06F 2218/08; G06F 2218/12

(57) ABSTRACT

Edge computing units that are outfitted with signal receivers and provided at local sites or edge locations are configured to capture RF signals and process the RF signals using transformer models. A spectrum encoder of a transformer model performs attention on frequency-encoded features extracted from spectrograms of the RF signals and features extracted from representations of RF signals associated with discrete RF events, and embeddings generated by the spectrum encoder are decoded to classify the RF signals or a source of the RF signals. Additionally, a spectrum decoder of a transformer model is configured to receive a query for information and to generate a response to the query using a spectrum decoder that performs attention on embeddings received from a spectrum encoder, as well as frequency-encoded features representative of the query, and features representative of semantic information regarding RF signals and sources of the RF signals.

### BACKGROUND

The radio frequency (or “RF”) spectrum is generally defined as the portion of the electromagnetic spectrum that includes radio waves. Today, many systems and machines emit signals within the RF spectrum for applications in a variety of fields.

For example, personal devices such as smartphones or other handheld devices (e.g., “Walkie-Talkies”), wireless routers, and other systems all rely on RF signals to transmit or receive information or data for communications purposes. Similarly, radio transmitters, television transmitters, and orbiting satellites transmit or receive RF signals for radio, television or Internet communications, or to provide positioning services. Likewise, many fixed stations and mobile vehicles also use RF signals in radar to track moving objects, to detect or predict weather patterns, or to conduct surveillance operations.

Thus, at any given time, and in any given location, humans may be surrounded or even bombarded by emissions of RF signals from any number of sources, such as aircraft transponders, radar systems, airborne or seaborne navigation devices, radio transmitters, orbiting satellites, communications towers, and others.

Detecting RF signals, and classifying sources from which the RF signals were emitted, or locations of such sources, are complex tasks that are subject to many technical and practical challenges, and such challenges may be amplified in environments that are known or believed to include multiple sources of RF signals. In view of the proliferation of mobile devices and mobile communications, the RF spectrum is increasingly crowded or congested, and many detected RF signals appear to overlap or interfere with one another. Moreover, many environments are commonly subjected to noise from natural sources, such as lightning or the cosmos, or man-made systems, such as power transmission equipment or other electronic components, that may mask or conceal RF signals. Furthermore, processing and classifying RF signals or their respective sources commonly require substantial processing capacity and computing power, which is sometimes not available in environments where the detection of RF signals and the classification or location of their sources is required.

### BRIEF DESCRIPTION OF THE DRAWINGS

FIGS. 1A through 1F are views of aspects of one system in accordance with embodiments of the present disclosure.

FIGS. 2A and 2B are views of aspects of an edge computing apparatus in accordance with embodiments of the present disclosure.

FIGS. 3A and 3B are views of aspects of one system in accordance with embodiments of the present disclosure.

FIG. 4 is a view of aspects of one system in accordance with embodiments of the present disclosure.

FIG. 5 is a flow chart of one process in accordance with embodiments of the present disclosure.

FIG. 6 is a view of aspects of one system in accordance with embodiments of the present disclosure.

FIGS. 7A through 7C are views of aspects of one system in accordance with embodiments of the present disclosure.

FIGS. 8A and 8B are views of aspects of one system in accordance with embodiments of the present disclosure.

FIGS. 9A and 9B are views of aspects of one system in accordance with embodiments of the present disclosure.

FIGS. 10A and 10B are a flow chart of one process in accordance with embodiments of the present disclosure.

FIG. 11 is a view of aspects of one system in accordance with embodiments of the present disclosure.

FIGS. 12A and 12B are views of aspects of one system in accordance with embodiments of the present disclosure.

FIGS. 13A and 13B are views of aspects of one system in accordance with embodiments of the present disclosure.

FIGS. 14A through 14C are views of aspects of one system in accordance with embodiments of the present disclosure.

FIGS. 15A and 15B are views of aspects of one system in accordance with implementations of the present disclosure.

### DETAILED DESCRIPTION

The systems and methods of the present disclosure are directed to detecting emissions of RF signals during events (or “RF events”), classifying sources of the RF signals, and determining locations of such sources using artificial intelligence solutions. More specifically, the systems and methods of the present disclosure are directed to generating spectrograms or other two-dimensional representations of RF signals, and using machine learning models having transformer architectures to interpret the representations and to evaluate the RF signals based on such representations accordingly. Machine learning models of the present disclosure, or “transformer models,” may include encoders that are configured to generate features or embeddings representative of two-dimensional spectrograms, in a manner similar to that of a vision transformer, and to encode such features or embeddings with frequencies or other information or data representative of RF signals or the spectrograms. For example, an encoder may perform attention (e.g., multi-modal attention) on sets of features extracted from the two-dimensional representations, and sets of features extracted from information or data regarding any number of selected RF events.

Embeddings generated by performing attention on such features may then be decoded or otherwise interpreted to determine information regarding emissions of the RF signals, or sources of the RF signals, including but not limited to identifiers of the sources of the RF signals, locations from which the RF signals were emitted, or characterizations of events during which the RF signals were emitted. For example, embeddings may be processed to determine whether similar emissions of RF signals or similar events including such emissions have been previously detected, or to otherwise compare attributes of such emissions or such events to emissions or events that have been previously detected. Embeddings may also be utilized to predict other events or occurrences that may be expected to occur in the future, based on embeddings representative of similar emissions of RF signals that were previously detected prior to such events or occurrences.

In some implementations, machine learning models of the present disclosure may include decoders that are configured to generate responses to queries for information based on embeddings generated by encoders of the machine learning models based at least in part on sets of features extracted from two-dimensional representations of captured RF signals. The queries for information may include utterances or entries of spoken words or text-based entries received from sensors, devices or other assets. Semantic information such as books, databases or other authorities regarding RF signals, RF sources or RF events may be processed to generate sets of features therefrom. Embeddings generated by encoders of the present disclosure may be decoded, along with the sets of features generated from the semantic information, to identify responses to the queries of information, and such responses may be presented to one or more people by displaying sets of words of the responses, playing sounds representing the responses aloud, or in any other manner.

In some implementations, machine learning models of the present disclosure may operate on edge computing units in the form of ruggedized, autonomous systems that may be deployed to harsh environments with limited or unreliable power or network connectivity. Moreover, in some implementations, edge computing units may include one or more all-digital receiver components that are specifically configured for advanced RF signal processing and analysis, and include one or more chips that are supercooled to extremely low temperatures, as well as interface electronics and field programmable gate array-based post-processing modules that are maintained at room temperatures. Alternatively, the edge computing units may include one or more quantum receivers, or any other components for capturing and processing RF signals across the RF spectrum.

Additionally, in some implementations, receivers of RF signals may be fixed or mobile in nature, and may capture and process RF signals in real time or near-real time, or in one or more batch processes. In some implementations, a receiver may capture RF signals while in motion within an environment and transmit data regarding such signals to a computer system, such as an edge computing unit, that processes such RF signals in accordance with one or more implementations of the present disclosure. Furthermore, in some implementations, RF signals (or two-dimensional representations of the RF signals, or features generated based on the RF signals) may be processed by an edge computing unit that captured the RF signals, or by another edge computing unit.

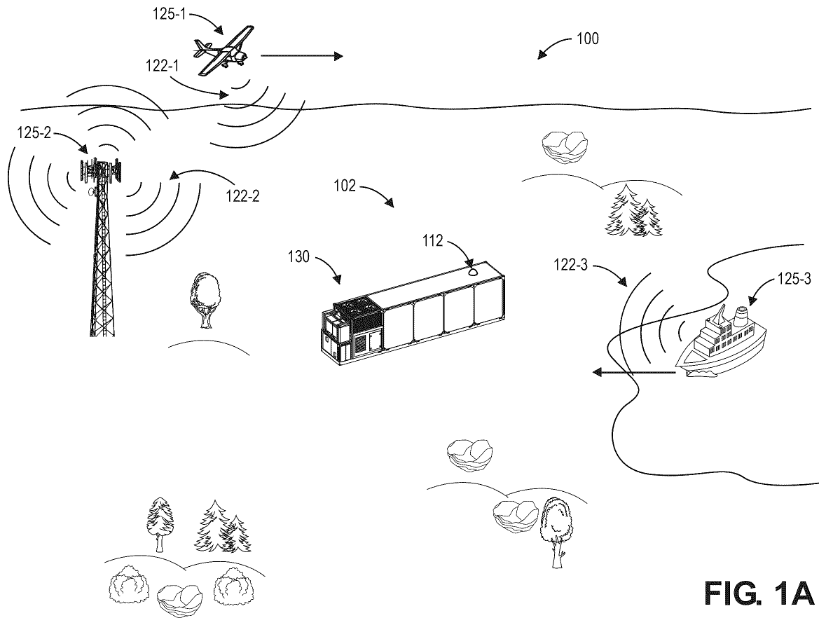

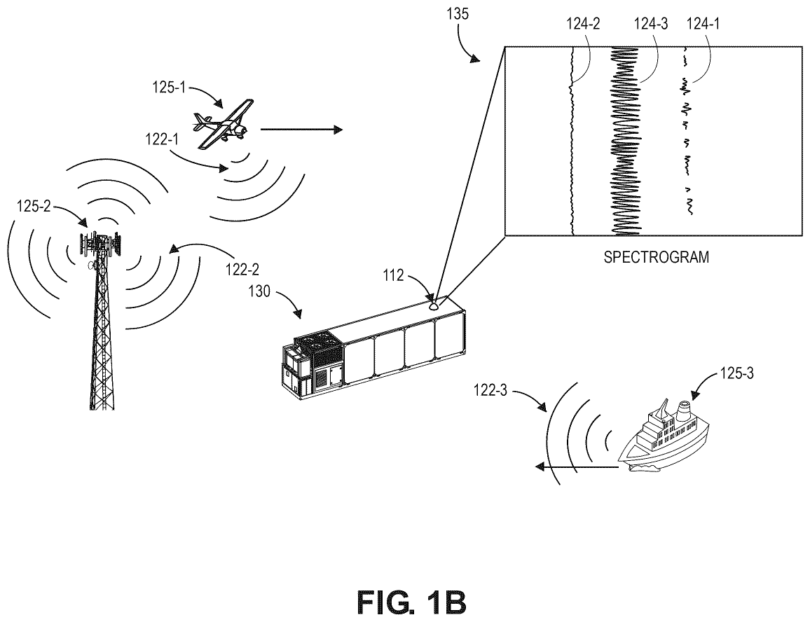

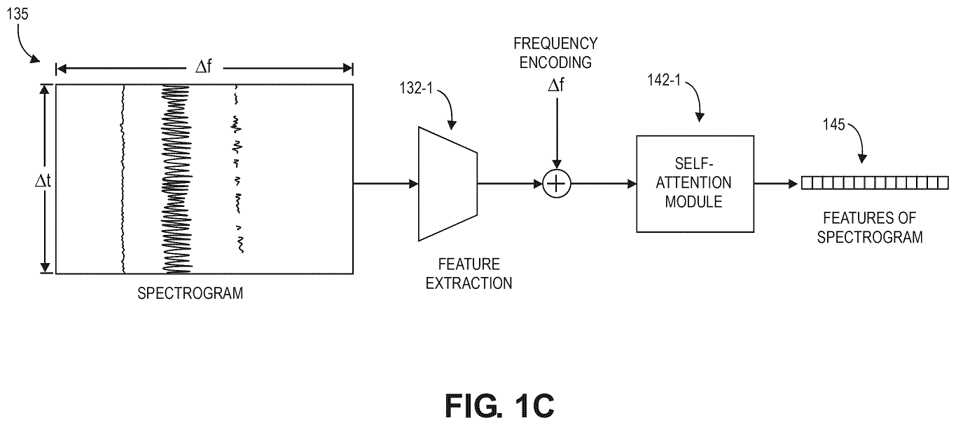

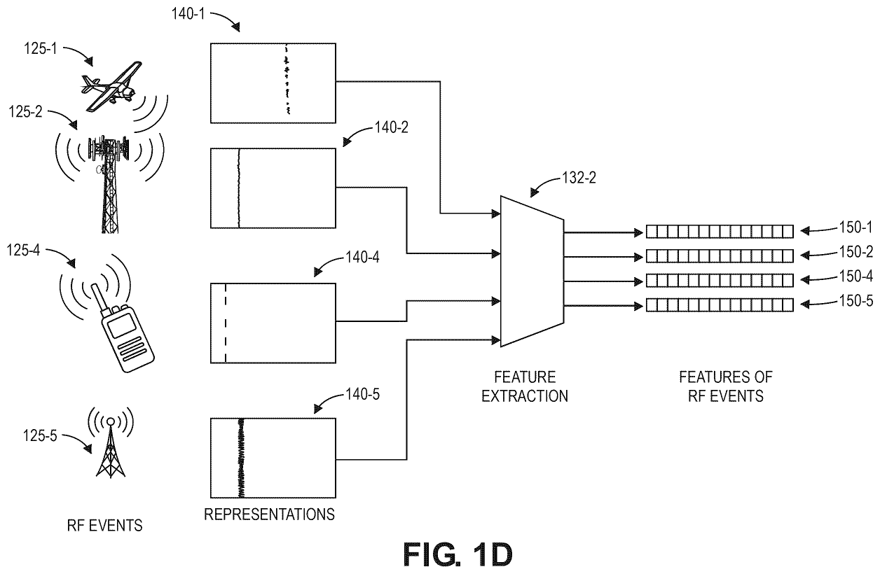

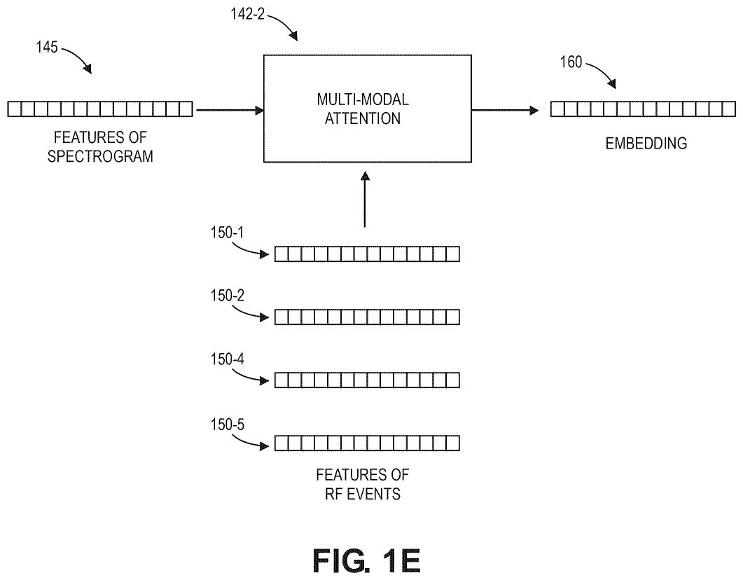

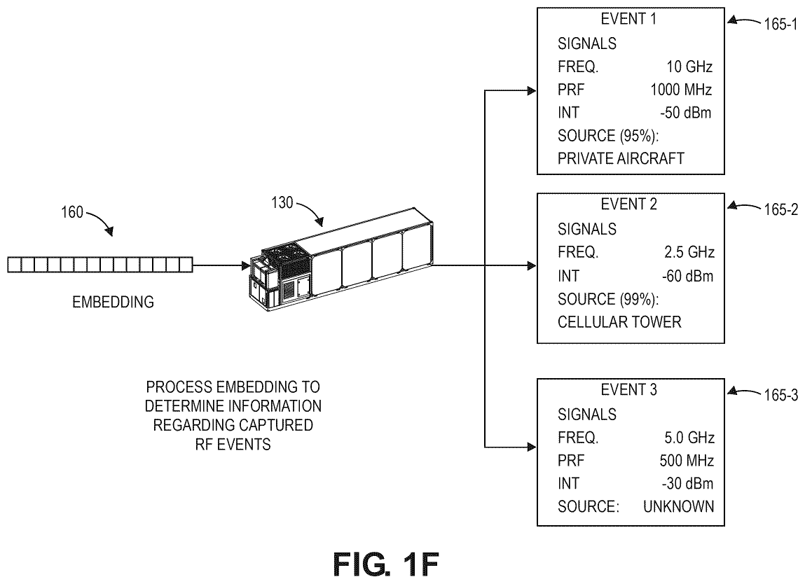

Referring to FIGS. 1A through 1F, views of aspects of one system in accordance with implementations of the present disclosure are shown. As is shown in FIG. 1A, an environment 100 (or a theater) includes an edge computing unit 130 including a receiver 112 provided at a local site 102. The edge computing unit 130 may be in communication with any number of devices or systems at the local site 102 over one or more local networks, and also with any number of devices or systems at remote locations over an external network that may include the Internet in whole or in part. For example, the edge computing unit 130 may be configured to access an external network or any external processing systems by way of one or more satellites or any other communication systems, which may provide a backhaul connection with the external network. In some implementations, the local site 102 may be a location where power or network connectivity from traditional power grids or other sources, e.g., alternating current (“AC”) power in any number of phases and at any frequency or voltage, or direct current (“DC”) power at any voltage, are limited or unavailable at one or more times during any given day. Moreover, in some implementations, the local site 102 may include any number of assets, such as systems or components such as cameras or other sensors for capturing or sensing information or data, as well as manned or unmanned vehicles of any type or form.

As is further shown in FIG. 1A, the environment 100 may further include any number of sources of RF signals that are emitted at any frequency or wavelength and intensity or strength. For example, as is shown in FIG. 1A, an aircraft 125-1 flying over or within a vicinity of the environment 100 emits one or more RF signals 122-1. A communications tower 125-2 within the environment 10 emits one or more RF signals 122-2. A seagoing vessel 125-3 sailing near or within a vicinity of the environment 100 emits one or more RF signals 122-3. Such RF signals 122-1, 122-2, 122-3 may include, but need not be limited to, broadcast signals, communication signals, radar signals, or any others, and may be transmitted in any frequency ranges, according to any modulation type (e.g., amplitude modulation, frequency modulation, phase modulation, or others), and for any purpose. Alternatively, any number of other RF signals may be emitted from any other sources, which may be in fixed positions or mobile, and may be located in or within a vicinity of the environment 100.

The edge computing unit 130 may be a computer system that includes any number of servers, processors, data stores, transceivers, switches, or other computer components or systems, as well as any number of power units, environmental control systems, isolation systems, or systems. Power units of the edge computing unit 130 may include any number of batteries, diesel engines, solar panels, or other power sources. Environmental control systems of the edge computing unit 130 may include any number of heating units, air conditioning units, fans, dampers, valves, humidifiers, dehumidifiers, or other systems for controlling environmental conditions within or around the edge computing unit 130. Isolation systems of the edge computing unit 130 may include any number of components for isolating internal portions of the edge computing unit 130 from an external environment at the local site 102, and may form or define chambers having any number of covers, sides, bottoms, doors, or other components formed from any suitable materials. Alternatively, or additionally, the edge computing unit 130 may include any number of other components or systems.

The receiver 112 may be any component or system that is configured to capture emissions of RF signals at any frequency or wavelength and any intensity or strength. In some implementations, the receiver 112 may include one or more all-digital components that are specifically configured for advanced RF signal processing and analysis, including but not limited to superconductor chips formed from niobium or other metals that are maintained at extremely low temperatures, such as approximately twenty degrees Kelvin (or negative 253.15 degrees Celsius) or lower, as well as interface electronics and field programmable gate array-based post-processing modules that may be maintained at room temperatures. In some implementations, the receiver 112 may operate at extremely high clock frequencies and directly digitize RF signals over broad ranges of bands.

In some implementations, data captured using the receiver 112 may be stored in one or more data stores provided on the edge computing unit 130, which may be optimized to receive streams of data captured at very high speeds, and may include one or more rack-mounted redundant arrays of independent disks (or “RAID” arrays).

The receiver 112 and other components of the edge computing unit 130 may be provided in a housing, such as a containerized unit, that is configured to maintain such components at desired temperatures, pressures, humidity levels or others, while protecting such components against the elements or any other adverse conditions at the local site 102. The edge computing unit 130 may have been transported to the local site 102 by one or more external propulsion units, e.g., aircraft, road tractors, trailers or trains, and may include one or more motors or other systems for reorienting or repositioning itself at the local site 102.

The edge computing unit 130 may be programmed or otherwise configured to generate spectrograms or other two-dimensional representations of RF signals captured by the receiver 112. For example, as is shown in FIG. 1B, the edge computing unit 130 may generate a spectrogram 135 by transforming the RF signals 122-1, 122-2, 122-3 from a time domain to a frequency domain, and generate plots 124-1, 124-2, 124-3 of the respective frequencies over time, with signal powers or intensities of the RF signals 122-1, 122-2, 122-3 shown according to a color gradient. The RF signals 122-1, 122-2, 122-3 may be transformed by a Fast Fourier Transform or another process, and outputs of the Fast Fourier Transform may be stacked to depict the plots 124-1, 124-2, 124-3 in a waterfall plot that resembles a cascading stream of data. The spectrogram 135 may be a two-dimensional representation of the plots 124-1, 124-2, 124-3 over a selected period of time.

In accordance with implementations of the present disclosure, spectrograms or other two-dimensional representations of captured RF signals may be processed by one or more transformer models or other machine learning models (or algorithms, systems or techniques) to generate sets of features therefrom. The sets of features may include any number of characteristics extracted from raw data representing the captured RF signals, such as pre-determined descriptors, e.g., edges, corners, blobs, texture patterns, outputs of scale-invariant feature transforms (or “SIFT”), a histogram of oriented gradients (or “HOG”), Laplacians, or others, as well as learned representations, such as activations from a neural network layer in a deep neural network. As is shown in FIG. 1C, the spectrogram 135 may be provided to a feature extraction module 132-1 to extract a set of features 145 therefrom, and the set of features 145 may be encoded with one or more frequency ranges Δf represented in the spectrogram 135. Alternatively, or additionally, the set of features 145 may be encoded with any other information or data regarding the spectrogram 135 or the RF signals represented therein. Additionally, a self-attention module 142-1 may perform self-attention on the encoded features, to thereby determine or weigh levels of importance of different portions of the spectrogram 135, as encoded with the frequency ranges Δf, to one another. The self-attention module 142-1 may be performed using a single head or multiple heads, and using a single set of query inputs, key inputs or value inputs, or multiple sets of query inputs, key inputs and value inputs.

Similarly, the edge computing unit 130 may generate sets of features representing RF events. The sets of features may be generated based on spectrograms or other two-dimensional representations of RF signals emitted during the RF events, as well as any other information or data regarding the RF events, including but not limited to attributes or characteristics of the RF signals or sources of the RF signals, as well as locations at which the RF signals or sources are typically encountered, or other events or occurrences that may be typically associated with the RF events.

As is shown in FIG. 1D, a spectrogram 140-1 (or another two-dimensional representation) is generated from an RF event involving RF signals captured during radar emissions by the aircraft 125-1 (or another aircraft of the same type, form or class of the aircraft 125-1), while a spectrogram 140-2 is generated from an RF event involving RF signals captured during communications transmissions by the communications tower 125-2 (or another communications tower that operates in a manner similar to the communications tower 125-2). Additionally, a spectrogram 140-4 is generated from an RF event involving RF signals captured during communications transmissions by a handheld communications device 125-4 (e.g., a Walkie-Talkie), and a spectrogram 140-5 is generated from an RF event involving RF signals captured during communications transmissions by a radio tower 125-5. Each of the spectrograms 140-1, 140-2, 140-4, 140-5 and any other information or data regarding RF events including emissions of the RF signals by the respective sources 125-1, 125-2, 125-4, 125-5 may be provided as inputs to a feature extraction module 132-2 to extract sets of features 150-1, 150-2, 150-4, 150-5 therefrom. The RF signals may have been captured by the receiver 112 or by any other sensor during the RF events, and the spectrograms 140-1, 140-2, 140-4, 140-5 may have been generated based on such signals by the edge computing unit 130 or by any other device or system following the RF events.

In some implementations, the feature extraction module 132-2 may be executed on the respective spectrograms 140-1, 140-2, 140-4, 140-5 representing signals of the RF events along with any other information or data regarding the RF events by the edge computing unit 130, and the sets of features 150-1, 150-2, 150-4, 150-5 may be stored thereon. In some other implementations, however, the feature extraction module 132-2 may be executed by another computing system in communication with the edge computing unit 130, and the sets of features 150-1, 150-2, 150-4, 150-5 may be retrieved therefrom, as necessary. The spectrograms 140-1, 140-2, 140-4, 140-5 or the sets of features 150-1, 150-2, 150-4, 150-5 may be stored in association with information or data regarding the respective sources 125-1, 125-2, 125-4, 125-5 or the RF signals 122-1, 122-2, 122-4, 122-5 in one or more data stores, which may be provided on the edge computing unit 130 or on another computer device or system in any location.

Additionally, in some implementations, features or embeddings regarding RF events may be synthetically generated. For example, where information or data regarding a source of RF signals, such as frequencies (or wavelengths), pulse repetition frequencies (or pulse widths), or intensities (or powers) of RF signals emitted by the source is known, a two-dimensional representation of such signals and any other information regarding RF events involving the transmission of such signals by the source may be generated without actually having captured such signals. The two-dimensional representation may then be processed to generate sets of features regarding the RF events, which may then be stored in association with information or data regarding the source or the RF signals, e.g., in one or more data stores of the edge computing unit 130 or on another computer device or system. Alternatively, features or embeddings regarding RF events may be synthetically generated by modifying RF signals captured during actual RF events, e.g., to amplify such signals, to add noise to such signals, or to remove noise from such signals, before generating spectrograms or other two-dimensional representations based on such signals and any additional information or data regarding the actual RF events, and generating features from the spectrograms or the other two-dimensional representations.

As is further shown in FIG. 1E, attention is performed on the sets of features 145 generated from the spectrogram 135 of the RF signals 122-1, 122-2, 122-3 in the frequency domain as shown in FIG. 1C and the sets of features 150-1, 150-2, 150-4, 150-5 generated from the spectrograms 140-1, 140-2, 140-4, 140-5 of the RF events shown in FIG. 1D. For example, the sets of features 150-1, 150-2, 150-4, 150-5 may be provided as query inputs and the set of features 145 encoded with the frequency ranges may be provided as a key input and a value input, to a multi-modal attention module 142-2 to generate an embedding 160, or a learned, low-dimensional vector representation that represents semantic or contextual relationships between inputs and is indicative of meaningful information in terms of context, or semantics between such inputs. The embedding 160 may represent portions of the RF signals 122-1, 122-2, 122-3 that are deemed most relevant to the RF signals that are emitted during the RF events, as represented in the sets of features 150-1, 150-2, 150-4, 150-5.

As is shown in FIG. 1F, the embedding 160 may be decoded or otherwise processed by the edge computing unit 130 to generate information regarding RF events including the emissions of RF signals 122-1, 122-2, 122-3 captured by the receiver 112 of the edge computing unit 130, as shown in FIGS. 1A and 1B. For example, the edge computing unit 130 may describe one event 165-1 represented in the embedding 160 as a capture of RF signals at a frequency of approximately ten gigahertz (or 10 GHz), a pulse repetition frequency of approximately one thousand megahertz (or 1000 MHz), and an intensity of negative fifty decibel-milliwatts (or −50 dBm). Likewise, the edge computing unit 130 may describe one event 165-2 represented in the embedding 160 as a capture of RF signals at a frequency of approximately two-and-one-half gigahertz (or 2.5 GHz) and an intensity of negative sixty decibel-milliwatts (or −60 dBm), and another event 165-3 represented in the embedding 160 as a capture of RF signals at a frequency of approximately five gigahertz (or 5.0 GHz), a pulse repetition frequency of approximately five hundred megahertz (or 500 MHz), and an intensity of negative thirty decibel-milliwatts (or −30 dBm).

The edge computing unit 130 may further characterize the event 165-1 as having been emitted by a private aircraft, with a substantially high confidence level of approximately ninety-five percent (or 95%), and may also characterize the event 165-2 as having been emitted by a cellular telephone tower, with a substantially high confidence level of approximately ninety-nine percent (or 99%). The edge computing unit 130 may also characterize the event 165-3 as having been emitted by an unknown source.

Alternatively, the embedding 160 may be processed or characterized in any other manner. In some implementations, where a query for information is received regarding one or more RF signals, a source of RF signals, or a status of any RF signals that may or may not be present within an environment, the embedding 160 may be provided as an input to a decoder trained to generate a text-based response to the query for information. For example, the embedding 160 may be provided as inputs to a multi-modal attention module along with embeddings representative of a query for information received from a person associated with an edge computing unit and embeddings generated based on semantic information regarding RF signals or sources. Outputs received from the multi-modal attention module may be processed to generate a response to the query for information, which may be presented to the person in any manner, such as by causing sounds representing words of the response to be played aloud to the person, or by displaying the words of the response on a screen to the person.

Accordingly, the systems and methods of the present disclosure may be used to capture RF signals emitted by any number of sources during events, and at any frequency or intensity, and classify the RF signals or the sources using one or more machine learning models (or algorithms, systems or techniques) that incorporate transformer architectures therein. Data regarding RF signals that are captured by a receiver may be transformed to a frequency domain and a spectrogram or another two-dimensional representation of such signals may be generated accordingly. The spectrogram or other two-dimensional representation may be processed to extract any features therefrom. In a similar manner, spectrograms or other two-dimensional representations of RF signals associated with other RF events may be processed to extract features therefrom. Such features may include characteristics extracted from raw data representing the RF signals, such as pre-determined descriptors, e.g., edges, corners, blobs, texture patterns, outputs of scale-invariant feature transforms (or “SIFT”), a histogram of oriented gradients (or “HOG”), Laplacians, or others, as well as learned representations, such as activations from a neural network layer in a deep neural network. One or more embeddings may be generated by performing multi-modal attention on the representations of the RF signals captured by the receiver and the representations associated with the other RF events to classify the RF signals.

Embeddings generated from spectrograms or other two-dimensional representations of captured RF signals may include learned, low-dimensional vector representations that capture semantic or contextual relationships between inputs and may include extracted and encoded meaningful information in terms of relationships, context, or semantics. The embeddings of the present disclosure may be generated, stored and utilized for any purpose. In some implementations, an embedding generated from a spectrogram or another two-dimensional representation of captured RF signals may be added to a database along with any other information or data regarding the captured RF signals, including but not limited to a location of a receiver (e.g., an edge computing unit) that captured the RF signals, time stamps or other identifiers of dates or times at which the RF signals were captured, or any information or data regarding activity occurring within a vicinity or an operating range of the location of the receiver at the dates or times, such as the movement or presence of any other objects or systems within the vicinity. Embeddings may also be stored in association with information or data captured by any other systems or in any other modalities, and may identify potential sources of the RF signals, e.g., either specifically by name or generally by a type, a class, or a category of such sources, as well as an anticipated or predicted reason or purpose of the emission of the RF signals. Embeddings may be further stored in association with any other attributes of the RF signals, e.g., frequencies or wavelengths, attributes or strengths, or any other attributes.

Additionally, in some implementations, embeddings generated from spectrograms or other two-dimensional representations of captured RF signals may be decoded by a classification head or another component of a machine learning model and interpreted to determine any information or data regarding the RF signals represented therein. In some implementations, the embeddings may be interpreted to detect or classify an RF event with which the RF signals are associated, or to match frequencies of the RF signals across multiple bands. The embeddings enable emissions of RF events to be segmented and processed independently over time, and clusters of such embeddings may be formed according to any type or form of analyses, such as by k-means clustering, to group the embeddings based on the similarity of their respective features. Thus, embeddings that are generated from features of spectrograms or other two-dimensional representations of subsequently captured RF signals may be compared to such clusters, and assigned to one of such clusters for classification or other purposes, such as to determine whether the RF signals are similar to any previously captured RF signals. Alternatively, embeddings that are generated from features of spectrograms or other two-dimensional representations of subsequently captured RF signals may be compared to individual embeddings, such as according to a k-nearest neighbor analysis, a similarity analysis, or a distance measure, for classification or other purposes. Where an emission of RF signals is unable to be identified or attributed to a source based on embeddings generated from features of spectrograms or other two-dimensional representations, information or data regarding the RF signals may be provided to one or more humans for review.

In some implementations, embeddings generated based on spectrograms or other two-dimensional representations may be interpreted to generate text-based responses to queries for information. For example, a query for information may relate to a source of an RF signal, such as whether the source of the RF signal is a specific entity, whether the source of the RF signal is affiliated with a specific organization, or friendly or adverse to the organization, and an embedding generated based on a spectrogram or another two-dimensional representation of the RF signal may be processed to generate a response to the query. Alternatively, or additionally, the query may relate to the RF signals themselves, such as whether RF signals represented therein are similar to those that have been previously encountered or captured in a location, whether the RF signals are typically encountered or captured in that location, or whether the emission of the RF signals violates an established law, rule or standard in that location, and embeddings generated based on spectrograms or other two-dimensional representations of the RF signals may be processed to generate a response to the query.

The RF spectrum represents electromagnetic signals as a function of frequency and time, and such signals are often analyzed in frequency bands. Generally speaking, the RF spectrum is divided into bands, including a low frequency (or “LF”) band between approximately thirty kilohertz and three hundred kilohertz (or 30 kHz to 300 kHz), a medium frequency (or “MF”) band between approximately three hundred kilohertz and three megahertz (or 300 kHz to 3 MHz), a high frequency (or “HF”) band between approximately three megahertz and thirty megahertz (or 3 MHz to 30 MHz), a very high frequency (or “VHF”) band between approximately thirty megahertz and three hundred megahertz (or 30 MHz to 300 MHz), an ultra-high frequency (or “UHF”) band between approximately three hundred megahertz and three gigahertz (or 300 MHz to 3 GHz), a super-high frequency (or “SHF”) band between approximately three gigahertz and thirty gigahertz (or 3 GHz to 30 GHz), and an extremely high frequency (or “EHF”) band between approximately thirty gigahertz and three hundred gigahertz (or 30 GHz to 300 GHz).

RF signals are frequently depicted as time-frequency representations, such as spectrograms, and the representations may be treated as two-dimensional data, analogous to images. Representing RF signals in a two-dimensional manner enables the use of transformer architectures that have been developed for image-based tasks. Accordingly, the RF spectrum may be converted into a two-dimensional format, such as time vs. frequency, or power vs. frequency, using spectral analysis techniques such as large Fast Fourier Transforms, Short-Time Fourier Transforms (or “STFT”), wavelet transforms, or other techniques. Each sample of the RF spectrum, or “slice,” that represents frequency over time may be treated in a manner similar to that of a pixel grid in image processing.

The systems and methods of the present disclosure may segment an RF spectrum into tokens, each representing specific frequency-time or frequency-power bins. For example, in some implementations, an RF spectrum may be subject to a coarse-grained Fast Fourier Transform representation, and bin sizes determined from the coarse-grained Fast Fourier Transform representation may be refined by subsequent Fast Fourier Transform representations. Each token may correspond to a time-frequency patch containing information regarding a frequency band over a short period of time. The tokens will be flattened and embedded into fixed-size vectors for input into the transformer model.

In some implementations, an edge computing unit of the present disclosure may include one or more all-digital receiver components that are specifically configured for advanced radiofrequency signal processing and analysis. For example, in some implementations, a digital receiver component may include one or more superconductor chips formed from niobium or other metals that are supercooled to extremely low temperatures, but may feature interface electronics and field programmable gate array-based post-processing modules that are maintained at room temperatures. The digital receiver components may include low-pass delta modulators with phase modulation-demodulation architectures that are paired with digital in-phase and quadrature mixers and digital decimation filters. The digital receiver components may operate at extremely high clock frequencies and directly digitize RF signals over broad ranges of bands, from low frequencies to super-high frequencies, e.g., LF, MF, HF, VHF, UHF and portions of SHF.

In some implementations, data captured using receiver components provided onboard edge computing units of the present disclosure may be stored in one or more data stores provided on the edge computing units, which may be optimized to receive streams of data captured at very high speeds, and may include one or more rack-mounted redundant arrays of independent disks (or “RAID” arrays). In some implementations, the edge computing units of the present disclosure may be configured to execute large Fast Fourier Transforms to convert captured signals from a time domain to a frequency domain, in order to detect fine-grained events, multi-band signal correlations, and frequency shifts, as well as to discern closely spaced signals, or to aid in frequency-hopping transmissions.

The systems and methods of the present disclosure may rely on transformer-based machine learning models for RF spectrogram analyses. Such models of the present disclosure may include one or more attention mechanisms to capture long-range dependencies in time-series data, even in low layers.

The systems and methods of the present disclosure may further incorporate learning from audio spectrum transformers and vision transformers that are trained based on low-frequency signals or visual cues, thereby accelerating processes for training transformer-based models and also enhancing their performance, particularly in detecting time-sensitive radio frequency events in substantially high frequency bands. The transformer models may rely on Fast Fourier Transforms configured to transform substantially large numbers of points or data samples from a time domain into bins of a frequency domain, to improve granularity and fidelity in the processing of radiofrequency signals. The transformer models of the present disclosure leverage the transformer architecture, which may accommodate inputs of variable lengths and understand a global context, to enhance signal detection, classification and pattern recognition across multiple frequency bands, particularly in complex tasks.

The transformer models of the present disclosure may also convert raw spectral data into text-based descriptions or insights, adapting the transformer architecture to process spectral data, e.g., Fast Fourier Transform spectrograms, as a sequence of tokens representing both frequencies and intensities, and to provide special attention to tokenization, positional encoding, and domain-specific biases.

In accordance with some implementations of the present disclosure, a transformer model may process tokens generated from two-dimensional representations of RF spectrograms in a manner similar to how visual transformer models process patches derived from visual images. Because data regarding RF signals includes both spatial (e.g., frequency) and temporal (e.g., time) dimensions, positional encodings may be incorporated into the RF spectrograms in order to represent time and frequency. Such positional encodings may be analogous to two-dimensional positional encodings utilized by visual transformer models. Additionally, in accordance with some implementations of the present disclosure, a transformer model may include one or more self-attention mechanisms that enable the transformer model to selectively focus on significant frequency bands or time intervals when processing two-dimensional representations of RF spectrograms. Self-attention enables transformer models to identify most relevant portions of the RF spectrum for performing various tasks, such as text generation, signal classification, threat detection, event tracking, localization, or others.

Transformer models of the present disclosure may be pre-trained or trained in any manner. In some implementations, a transformer model may be trained using masked token prediction (or patch prediction), where portions of the RF spectrum are masked, and the transformer model predicts contents of masked portions based on contents of the unmasked portions. Accordingly, transformer models of the present disclosure may have an enhanced ability to learn from unlabeled data, thereby forming a solid foundation for tasks that are to be subsequently performed by the transformer models.

Moreover, in some implementations, machine learning models of the present disclosure may be subsequently trained or fine-tuned to perform one or more predetermined tasks. For example, a machine learning model that incorporates a transformer architecture of the present disclosure may be trained to generate sets of words or text from RF signals, e.g., “RF-to-text” generation. Such sets of words or text may describe RF signals that are captured, characterize such RF signals, and classify the RF signals as having originated from a previously known source, or indicate that the RF signals may have been emitted by an unknown source, based on a spectrogram analysis of the RF signals in accordance with implementations of the present disclosure.

Because data regarding RF signals often exhibit long-duration temporal structures, the transformer models of the present disclosure may further include one or more neural network features, such as recurrent neural networks or temporal convolutional networks, that may enhance the temporal modeling of the RF signals and enable the transformer models to capture long-range dependencies over time. Additionally, data regarding RF signals that are captured in accordance with implementations of the present disclosure may be subject to pre-processing or data augmentation techniques that are tailored to the specific RF signals, in order to ensure that the transformer models remain robust and operate at sufficiently high levels.

Moreover, the systems and methods of the present disclosure may apply RF-specific augmentations to data, such as random noise injection, frequency shifting, or time warping, in order to enhance the robustness of a transformer model. One or more synthetic datasets may be generated to validate and further develop the transformer models, and such datasets may focus on long-duration RF sequences to assess transmission detection and pattern-tracking.

Where a machine learning model of the present disclosure is configured to generate sets of words or text based on RF signals, the machine learning model may be properly trained using training data including RF signals, e.g., spectrograms or other two-dimensional representations of such signals, and accurate, relevant labels for such signals. Training data may be obtained from any number of sources, including but not limited to government records or databases maintained by the Federal Communications Commission or other organizations, such as the Universal Licensing System databases, Frequency Allocation Table databases, Equipment Authorization System databases, Spectrum Dashboard databases, or others. By incorporating domain-specific knowledge regarding communication protocols, modulation types, spectral patterns or other information into machine learning models of the present disclosure, such models may be particularly well-trained for complex tasks such as signal identification.

Furthermore, the systems and methods of the present disclosure may capture and process information or data regarding any type or form of RF signals that are emitted by any type or form of RF source during any type or form of RF event. For example, some sources of RF signals that may be captured and processed in accordance with implementations of the present disclosure may be publicly or privately owned, and may include sources that are available to civilians, such as communications systems, radar systems, or other systems that may be owned or operated by the general public. Alternatively, some other sources of RF signals that may be captured and processed in accordance with implementations of the present disclosure may be operated by one or more government entities, or may not be otherwise available to civilians. Such entities may include but need not be limited to law enforcement agencies or military groups, and sources operated by such entities may include voice or data communications systems, or radar systems, such as navigation radar systems, weather radar systems, fire control radar systems, or others. The sources of RF signals, or the events during which such RF signals are emitted, are not limited by any of the embodiments of the present disclosure.

Edge computing units of the present disclosure may play valuable roles in providing relevant machine learning and artificial intelligence resources to challenging environments, specifically with regard to applications that require processing in real time or near-real time, with high reliability and minimal latency. An edge computing unit executing such applications may process data received from high-bandwidth sensors or systems, including but not limited to cameras, light detection and ranging (or “LiDAR”) or time-of-flight sensors, accelerometers, fiber-optic sensors, radar or ultrasonic sensors, which may stream data at increasingly high rates. Where such sensors are provided in remote locations with sporadic or limited connectivity, analyzing data captured by such sensors in situ may be more feasible rather than transmitting such data to one or more remote systems operating in the “cloud.” Depending on numbers of sensors or systems that are operated to capture such data, much of the data will remain unanalyzed or unutilized.

Edge computing units of the present disclosure may have any size or shape, and take any form. In some implementations, edge computing units may be provided in standardized containers, thereby enabling such units to be rapidly transported to any locations by a single mode or in an intermodal fashion, e.g., by air, sea or land, and positioned in place using standard equipment such as cranes, forklifts, or other machinery. The edge computing units may contain or have ready access to critical infrastructure such as power, climate control systems, security features, fire protection systems or access control systems. The edge computing units may also include integrated hardware components and software applications programmed thereon prior to deployment, such that the edge computing units may be activated and placed into service following installation without delay.

Edge computing units of the present disclosure may further include sufficient power for sustaining operations of such units, and ensuring redundancy even during downtime such as maintenance, updating or repairs. The edge computing units may operate based on alternating current (“AC”) electrical power, direct current (“DC”) electrical power, or power from any other source. In some implementations, the edge computing units may operate on 480 volt, three-phase, 60 Hertz AC power. In some other implementations, the edge computing units may be configured for operation on 220 to 230 volt, single-phase AC power at any frequency. Alternatively, the edge computing units may operate using AC power or DC power at any voltage, power level or frequency.

Edge computing units of the present disclosure may also include any number of servers or other computer devices or systems, as may be required in order to execute any desired applications or perform any desired functions. In some implementations, the edge computing units may include server racks that are isolated or otherwise configured for resistance against shocks or vibrations during transportation or operations.

Edge computing units may be operated independently or as members of groups (e.g., a fleet of such units), and may communicate over local networks at local sites where the edge computing units are employed, e.g., via short-range wired or wireless networks, or over backhaul links to the Internet or other computer networks via wired, wireless or satellite connections. The edge computing units may be programmed with software applications for overseeing operations at a local site, as well as power, data transmission and connectivity of the edge computing units, for simplifying the deployment and management of applications with asset-aware resource provisioning, for managing workloads deployed to edge computing units or other assets at local sites with automatic resource provisioning, job assignment or cancellation features, and for maintaining security and access controls for the edge computing units and other assets.

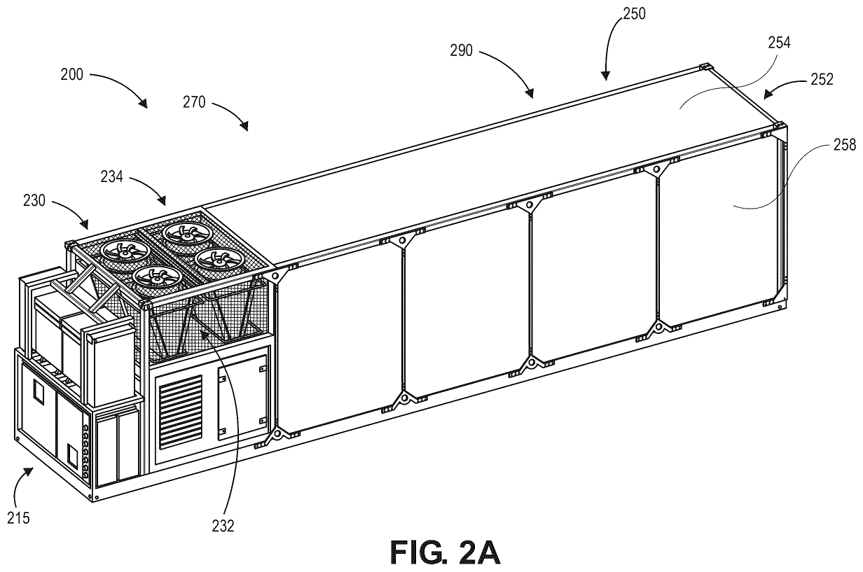

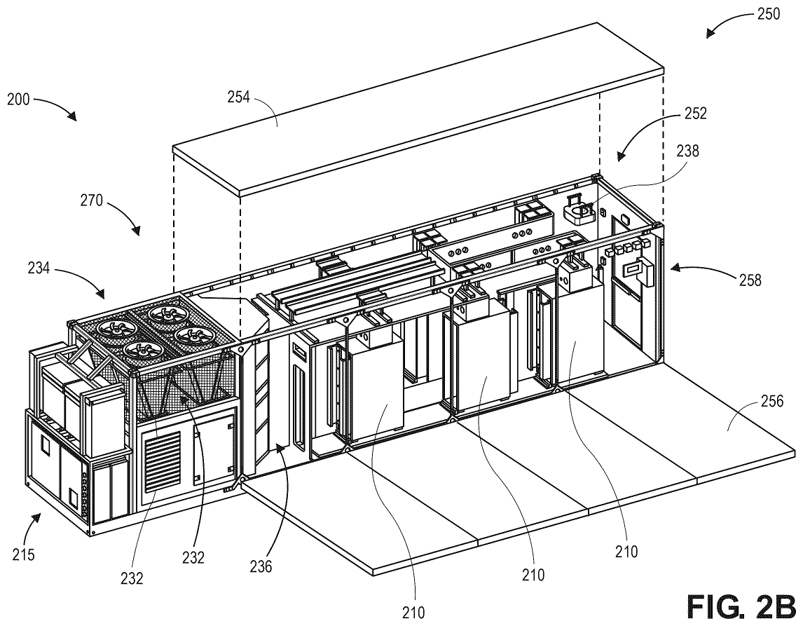

Edge computing units of the present disclosure may have any size, shape or dimensions, and may include any number of components or systems. Referring to FIGS. 2A and 2B, an edge computing apparatus 200 of the present disclosure is shown. As is shown in FIGS. 2A and 2B, the edge computing apparatus 200 comprises a plurality of server racks 210, a plurality of power units 215, a plurality of environmental control systems 230 and an isolation system 250 disposed in a housing 270 having a form of a containerized unit 290. The edge computing apparatus 200 may be deployed to particular sites or locations, which may be referred to herein as “local sites” or “edge locations,” using one or more external propulsion units such as helicopters, road tractors, ships, trailers, trains, or others, which may be configured to lift, carry or otherwise transport the edge computing apparatus 200 to such locations, e.g., over substantially long distances. Alternatively, the edge computing apparatus 200 may further include propulsion units that are integrated with the edge computing apparatus 200, such as motors, engines, drive train components, transmissions, axles, wheels or other features. For example, in some implementations, the edge computing apparatus 200 may be an integral component of a road tractor, a trailer or a train. In some implementations, the edge computing apparatus 200 may further include one or more internal propulsion systems, e.g., electrical motors, which may be used to subsequently move or relocate the edge computing apparatus 200 for short distances upon an arrival at a local site or an edge location.

The server racks 210 may include any number of computing components, units or systems. For example, in some implementations, each of the server racks may include one or more central processing units, as well as data stores or other memory components, networking systems, power supplies, high-performance computing units, e.g., graphical processing units, field programmable gate arrays, vision processing units, associative processing units, tensor processing units, neuromorphic chips, quantum processing units, or the like. Numbers of the respective processor units or other components within each of the server racks 210 may be selected for redundancy or for resiliency, or on any other basis. Moreover, the networking systems may include one or more routers, networking switches, out-of-band switches, or systems for communication between the respective server racks 210 or any number of components of the edge computing apparatus 200 within the housing 270, or for communication with any number of external systems (not shown).

The edge computing apparatus 200 may further include one or more power units 215, which may include any number of components for generating or storing energy in any form. For example, in some implementations, the power units 215 may include any number of batteries or other power cells, e.g., dry cell or wet cell batteries such as lead-acid batteries, lithium-ion batteries, nickel cadmium batteries or nickel metal hydride batteries, or any other type, size or form of batteries. In some implementations, the power units 215 may further include one or more diesel engines, electric engines, or engines or motors that are powered by any other source of energy, e.g., gasoline, natural gas, fuel cells, nuclear reactors, solar power, or others. The power units 215 of the edge computing apparatus 200 may be selected on any basis, such as their respective peak or mean voltages, peak or mean load currents, charge times, fuel capacities, or other attributes.

In some implementations, the power units 215 may be coupled to one or more solar panel arrays that are included in, coupled to, or otherwise associated with surfaces of the edge computing unit 200. For example, solar panel arrays may be attached to a top surface of the housing 270, or in any other portion of the housing 270. The solar panel arrays may be fixed in position, or foldable, collapsible, or otherwise movable between deployed and stowed positions, and exposed in order to generate electrical power using sunlight incident upon surfaces of the solar panel arrays. Electrical power generated by solar panel arrays may be transferred to the power units 215 and used to power the edge computing unit 200 and its constituent components.

The edge computing apparatus 200 may further include one or more environmental control systems 230 in order to maintain or establish a desired set of environmental conditions (e.g., temperature, pressure, humidity, or others) within the edge computing apparatus 200. For example, the environmental control systems 230 may include, but need not be limited to, one or more air conditioning units 232, fans 234, dampers 236 and heaters 238. The air conditioning units 232 may be formed from metals, plastics or other suitable materials and include any number of compressors, condensers, evaporators or other systems for maintaining or reducing air temperatures within the edge computing apparatus 200. The environmental control systems 230 may include any number of fans 234 for initiating air flows into the air conditioning units 232 or throughout the housing 270. The environmental control systems 230 may also include one or more dampers 236 for initiating, isolating or regulating flows of air into, throughout or out of the edge computing apparatus 200. The environmental control systems 230 may further include one or more heaters 238 of any type or form, e.g., electric, gas, kerosene, propane, or others, which may include any number of systems for maintaining or increasing air temperatures within the edge computing apparatus 200.

The environmental control systems 230 shown in FIGS. 2A and 2B are integral to the edge computing apparatus 200. Alternatively, or additionally, the edge computing system 200 may include any number of other environmental control systems (not shown) that operate in a standalone manner, external to the edge computing apparatus 200, in order to maintain or establish a desired set of environmental conditions within the edge computing apparatus 200.

As is shown in FIGS. 2A and 2B, the edge computing apparatus 200 may further include an isolation system 250 for isolating internal portions of the edge computing apparatus 200 from an external environment. The isolation system 250 may include a chamber 252 defined by a top cover 254, a plurality of sides 256 and a door 258.

The isolation system 250 may be configured to secure contents of the edge computing apparatus 200, e.g., the server racks 210 or others, and to protect such contents from the elements while also restricting unauthorized access or entry into the chamber 252. For example, the isolation system 250 may be closed and sealed to maintain the chamber 252 in any desired condition, e.g., at selected levels of temperature, pressure and humidity, and access to the chamber 252 may be provided by way of the door 258 following the operation of one or more access control systems, e.g., any remotely activated locking systems for such doors or other portals. Components of the isolation system 250 may have any quality, strength or security ratings. Furthermore, materials from which the cover 254, the sides 256 or the door 258 are formed or constructed may be selected to further provide radiofrequency shielding or to serve other protective functions for contents of the chamber 252.

Components of the isolation system 250 may also serve one or more other purposes, in addition to enclosing and securing portions of the edge computing apparatus 200 and contents of the chamber 252 therein. For example, portions of the isolation system 250 may also provide structural support to the housing 270 or any other portions of the edge computing apparatus 200.

The housing 270 may have any size or shape, and may take any form. In some implementations, the housing 270 may be a shipping container, or a similar vessel, of any standard shape or length. For example, in some implementations, the housing 270 may be a 40-foot vented shipping container constructed from steel and having one or more steel frames and/or castings that are sufficiently durable and strong enough to accommodate cargo, and to withstand impacts due to stacking, shocks or other contact during normal operation. In other implementations, the housing 270 may be made from a non-steel material, which may be appropriate where the containerized units 290 are deployed across wide geographical areas and need not be stacked, enabling lighter and more cost-effective materials other than steel to be used to form the housing 270. Additionally, in some implementations, the housing 270 may take the form of an intermodal container having standard dimensions including widths of approximately eight to eight-and-one-half feet (8 to 8.5 ft) and lengths of twenty, forty, forty-five, forty-eight or fifty-three feet (20, 40, 45, 48 or 53 feet) and heights of approximately eight to ten feet (8 to 10 ft), typically eight-and-one-half or nine-and-one-half feet (8.5 or 9.5 ft).

Implementations of the present disclosure may be operated, performed or executed by any type or form of computing device, apparatus or system, and need not be limited to the edge computing apparatus 200 of FIGS. 2A and 2B. Such devices, apparatuses or systems may include, but need not be limited to, cameras, mobile devices (e.g., smartphones, tablet computers, or the like), desktop computers, laptop computers, tablet computers, wearable devices (e.g., glasses or headsets for augmented reality or virtual reality, wrist watches, or others), servers, autonomous vehicles, robotic devices, televisions that may include one or more processors, memory components or data stores, displays, sensors, input/output (or “I/O”) devices, or other systems or components that may be configured to execute one or more sets of instructions or commands described herein.

Moreover, the systems and methods described herein may be implemented in electronic hardware, computer software, firmware, or any combination thereof. For example, in some implementations, processes or methods described herein may be operated, performed or executed using computer-readable media having sets of code or instructions stored thereon. Such media may include, but need not be limited to, random-access memory (“RAM”) such as synchronous dynamic random-access memory (“SDRAM”), read-only memory (“ROM”), non-volatile random-access memory (“NVRAM”), electrically erasable programmable read-only memory (“EEPROM”), FLASH memory, magnetic or optical data storage media, or others. Alternatively, or additionally, the disclosed implementations may be realized at least in part by a computer-readable communication medium that carries or communicates program code in the form of instructions or data structures and that may be accessed, read, and/or executed by a computer. Additionally, code or instructions may be executed by one or more processors or other circuitry. For example, in some implementations, such components may include electronic circuits or hardware, programmable electronic circuits such as microprocessors, graphics processing units (“GPU”), digital signal processors (“DSP”), central processing units (“CPU”) or other suitable electronic circuits, which may be executed or implemented using computer software, firmware, or any combination thereof, to perform the various operations described herein.

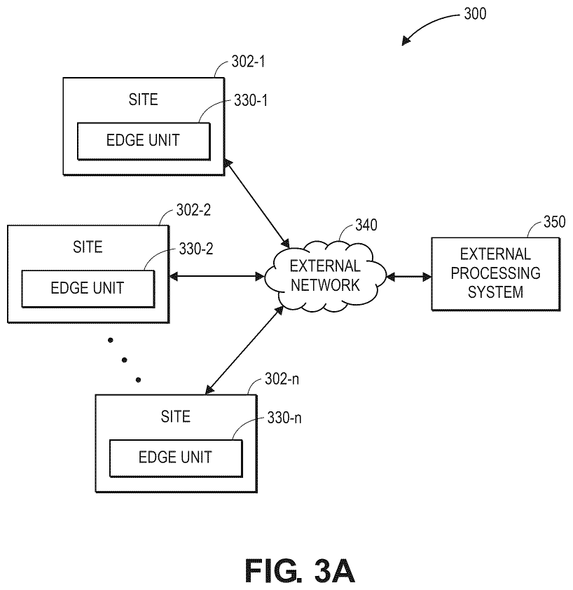

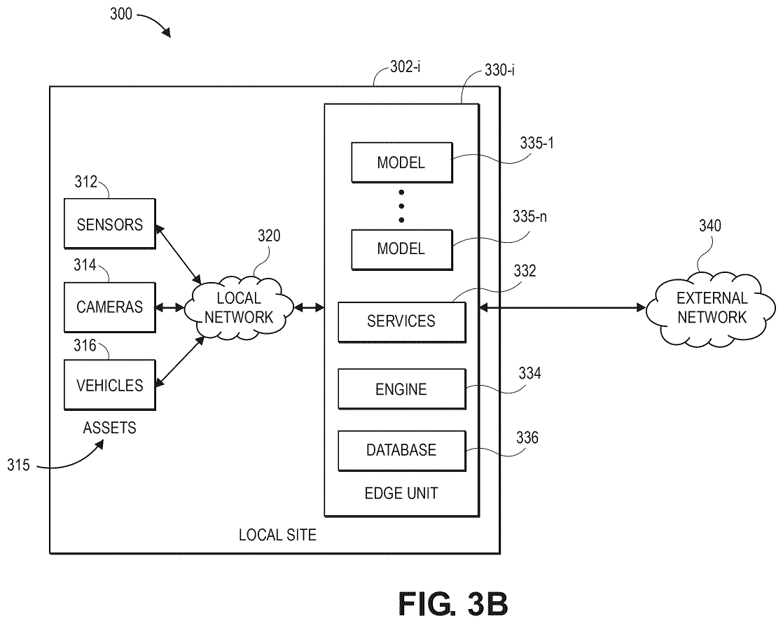

Edge computing apparatuses may be provided at any site or location and in any number, and may be connected to one another or any external systems over one or more external networks. Referring to FIGS. 3A and 3B, block diagrams of one system 300 in accordance with implementations of the present disclosure are shown.

As is shown in FIG. 3A, the system 300 includes a plurality of edge computing units (or systems) 330-1, 330-2 . . . 330-n and an external processing system 350. The plurality of edge computing units 330-1, 330-2 . . . 330-n are distributed at various local sites 302-1, 302-2 . . . 302-n, which may also be referred to herein as “edge locations,” and connected to one another and the external processing system 350 over an external network 340, which may include the Internet in whole or in part. Each of the sites 302-1, 302-2 . . . 302-n may include any number of edge computing units 330-1, 330-2 . . . 330-n.

As is shown in FIG. 3B, a representative one of the sites 302-1, 302-2 . . . 302-n including a representative one of the edge computing units 330-1, 330-2 . . . 330-n is shown. The edge computing unit 330-i may be used to implement or perform one or more aspects of the present disclosure. The edge computing unit 330-i may also be referred to as an “edge device” or an “edge compute unit.” In some implementations, the edge computing unit 330-i may be provided as a high-performance compute and storage (“HPCS”) and/or elastic-HPCS (“E-HPCS”) edge device. As is further shown in FIG. 3B, the edge computing unit 330-i may be in communication with any number of assets 315 at the site 302-i, including one or more sensors 312, one or more cameras 314, and one or more vehicles 316, or others, and may transmit information or data to such assets 315, or receive information or data from such assets 315, during operations of such assets 315 at the site 302-i, over one or more local networks 320. Such local networks 320 may include, but need not be limited to, one or more networks or other systems or techniques for communicating via any wired or wireless systems or protocols, including but not limited to cellular, Wireless Fidelity (or “Wi-Fi”), radio frequency identification (or “RFID”), near-field communication (or “NFC”) readers, Bluetooth®, or any other type of systems or protocols.

The site 302-i may be any one of a plurality of environments or deployment locations associated with the edge computing unit 330-i. The site 302-i may be a geographic location or area associated with an enterprise user (or another user) of edge computing, or an edge location in a data network topography in terms of data network connectivity. Alternatively, or additionally, the site 302-i may be both a geographic location of an enterprise user and an edge location in the data network topography.

The edge computing unit 330-i may be configured as a containerized edge compute unit or data center for implementing sensor data generation or ingestion and inference for one or more trained machine learning or artificial intelligence models provided thereon. For instance, the edge computing unit 330-i may include computational hardware components configured to perform inference for one or more trained machine learning or artificial intelligence models. As is shown in FIG. 3B, one portion of the edge computing unit 330-i may include hardware resources associated with or used to implement a first model 335-1, while another portion of the edge computing unit 330-i may include hardware resources associated with or used to implement an n-th model 335-n, where n may be any number of different machine learning or artificial intelligence models that may be operated simultaneously or in parallel. The model or models executing by the edge computing unit 330-i may also be referred to herein as an “edge model” or “edge models.”

In some cases, the system 300 may utilize the edge computing systems 330-1, 330-2. . . . 330-n provided at one or more of the sites 302-1, 302-2. 302-n to capture and process information or data received locally via the local networks 320, e.g., from any of the assets 315, and transmit the data to one or more external computing systems 350 over one or more external networks 340.

The local network 320 may provide any number of communication links between the edge computing system 330-i and respective ones of the assets 315. In some implementations, one or more aspects of the local network 320 may be implemented as a private or public “5G” network, “4G” network, “Long-Term Evolution” network, or other cellular network. Alternatively, or additionally, one or more aspects of the local network 320 may be implemented as a Wireless-Fidelity (or “Wi-Fi”) network, a Bluetooth® network, a Zigbee network, a Z-wave network, a Long Range (or “LoRa”) network, a Sigfox network, a Narrowband Internet of Things (or “NB-IoT”) network, or any other short-range wireless network.

The edge computing unit 330-i may receive different types of information or data from any number of the assets 315, and may transmit any type of information or data received from such assets 315 to any number of external computing systems 350. For example, in some implementations, the edge computing unit 330-i may receive streams of information or data from any of the sensors 312, which may include but need not be limited to one or more position sensors (e.g., Global Positioning Satellite system receivers, accelerometers, compasses, gyroscopes, altimeters), imaging devices (e.g., digital cameras, depth sensors, range cameras, infrared cameras, radiographic cameras or other optical sensors), speedometers (e.g., anemometers), thermometers, barometers, hygrometers, air monitoring sensors (e.g., oxygen, ozone, hydrogen, carbon monoxide or carbon dioxide sensors), infrared sensors, ozone monitors, pH sensors, magnetic anomaly detectors, metal detectors, radiation sensors (e.g., Geiger counters, neutron detectors, alpha detectors), attitude indicators, depth gauges or sound sensors (e.g., microphones, piezoelectric sensors, vibration sensors or other transducers for detecting and recording acoustic energy from one or more directions). The sensors 312 may also include any number of memory or storage components and processors, photosensitive surfaces, filters, chips, electrodes, clocks, boards, timers or any other relevant features (not shown) for aiding in their operation.

In some implementations, the edge computing unit 330-i may also receive streams of information or data from any of the cameras 314, which may include imaging devices of any type or form, e.g., digital cameras, depth sensors or range cameras, infrared cameras, radiographic cameras or other optical sensors. The cameras 314 may be configured to photograph or otherwise capture visual information or data (e.g., still or moving images in color or black and white that may be captured at any frame rates, or depth imaging data such as ranges), or associated audio information or data, or metadata, regarding objects or activities occurring at the site 302-i, or for any other purpose.

For example, the cameras 314 may be configured to capture or detect reflected light if the reflected light is within fields of view of the cameras 314, which may be defined as a function of a distance between an imaging sensor and a lens within one of the cameras 314, viz., a focal length, as well as positions of the cameras 314 and angular orientations of their respective lenses. The cameras 314 may further include manual or automatic features for modifying a field of view or orientation. For example, one or more of the cameras 314 may be configured in a fixed position, or with a fixed focal length (e.g., fixed-focus lenses) or angular orientation. Alternatively, one or more of the cameras 314 may be configured with actuated or motorized features for adjusting a position, a focal length (e.g., zooming the imaging device) or an angular orientation (e.g., the roll angle, the pitch angle or the yaw angle), by causing a change in a distance between the imaging sensor and the lens (e.g., optical zoom lenses or digital zoom lenses), a change in a position of the cameras 314, or a change in one or more of the angles defining the angular orientation of the cameras 314.

In some implementations, one or more of the cameras 314 may be an imaging device that is hard-mounted to a support or mounting that maintains the cameras 314 in a fixed configuration or angle with respect to one, two or three axes. Alternatively, one or more of the cameras 314 may be provided with one or more motors and/or controllers for manually or automatically operating one or more of the components, or for reorienting the axis or direction of the cameras 314, i.e., by panning or tilting the cameras 314. Panning the cameras 314 may cause a rotation within a horizontal plane or about a vertical axis (e.g., a yaw), while tilting the cameras 314 may cause a rotation within a vertical plane or about a horizontal axis (e.g., a pitch). Additionally, one or more of the cameras 314 may be rolled, or rotated about its axis of rotation, and within a plane that is perpendicular to the axis of rotation and substantially parallel to a field of view of the cameras 314.

In some implementations, the edge computing unit 330-i may also receive streams of information or data from any of the vehicles 316, which may include, but need not be limited to, one or more autonomous ground vehicles, one or more autonomous aerial vehicles (e.g., drones), or any other vehicle of any type, such as cars, trucks, trailers, freight cars, container ships or aircraft, which may be manned or unmanned (e.g., drones). Such vehicles 316 may be outfitted with any number of the sensors 312 or the cameras 314 described herein.

The vehicles 316 may receive information or data of any type or form from the edge computing unit 330-i, and transmit information or data of any type or form to the edge computing unit 330-i. The vehicles 316 may also receive information or data of any type or form from the edge computing unit 330-i, and transmit information or data of any type or form to the assets 315, e.g., the sensors 312 or the cameras 314. For example, in some implementations, the edge computing unit 330-i may provide information or data regarding any number of configurations or controls to the assets 315. In some other implementations, the edge computing unit 330-i may receive onboard camera feed and other sensor information, e.g., 3D range scanner, LiDAR, or odometry information for Simultaneous Localization and Mapping (or “SLAM”), from the vehicles 316, and may transmit any number of instructions to the vehicles 316.

Additionally, in some implementations, the edge computing unit 330-i may be further utilized to execute one or more sets of instructions for locally storing information or data, executing one or more of the models 335-1. 335-n, e.g., for inference, predictions or responses, or performing any other tasks or functions at the edge computing unit 330-i, with limited to no reliance on any external computing systems 350, e.g., in the “cloud.” For example, the edge computing unit 330-i may also be used to perform inference or generate predictions locally, e.g., by executing one or more of the trained or pretrained machine learning or artificial intelligence models 335-1 . . . 335-n that may be received from any external computing systems 350 or any other edge computing units.

Results or predictions generated by the models 335-1 . . . 335-n may be compressed and periodically uploaded by the edge computing unit 330-i to external computing systems 350, e.g., in the “cloud,” over the external network 340, which may include a satellite network configured to provide wireless satellite connectivity between the edge computing unit 330-i at the site 302-i and existing network infrastructure. Such results or predictions may be included in batch uploads transmitted over the external network 340, which may act as an Internet backhaul link, to any number of external computing systems 350. Additionally, in some implementations, results or predictions may be utilized immediately at the edge computing unit 330-i, and transmitted in compressed form to the external computing systems 350, e.g., in the “cloud,” at a later time. For example, the external network 340 may be used to provide periodic transmission or upload of compressed prediction or inference results, e.g., during high-bandwidth or low-cost availability hours associated with the external network 340.

In some implementations, results or predictions may be obtained by performing one or more essential functions or tasks using the models 335-1 . . . 335-n, while offloading more computationally intensive and/or less time-sensitive tasks from the edge computing unit 330-i to other machine learning or artificial models executed by one or more external computing systems 350, e.g., in the “cloud.” For example, in some implementations, machine learning or artificial intelligence models operated by remote computing systems, e.g., the external computing systems 350, may be utilized to train or fine-tune one or more of the models 335-1 . . . 335-n, and updated versions of such models may be transmitted to the edge computing unit 330-i over the external networks 340, e.g., via a network backhaul. In some implementations, the models 335-1 . . . 335-n may be trained, fine-tuned, retrained or replaced in an iterative or continuous manner. For example, in some implementations, the edge computing unit 330-i may be configured to perform scheduled or periodic downloads or updates of the models 335-1 . . . 335-n based on information or data received from the external computing systems 350. Downloads or updates of the models 335-1 . . . 335-n may be distributed to the edge computing unit 330-i in a “push” fashion, whereby the external computing systems 350 transmit updated or new models to the edge computing unit 330-i over the external networks 340, e.g., via a network backhaul, as updated or new models become available.

The edge computing unit 330-i may further include any number of services 332 for executing or operating with any external computing systems 350, e.g., in the “cloud,” as well as an engine 334 (e.g., a high-performance compute engine) for implementing or managing the models 335-1 . . . 335-n, and one or more databases (e.g., data stores) 336 for maintaining information or data of any type or form thereon.

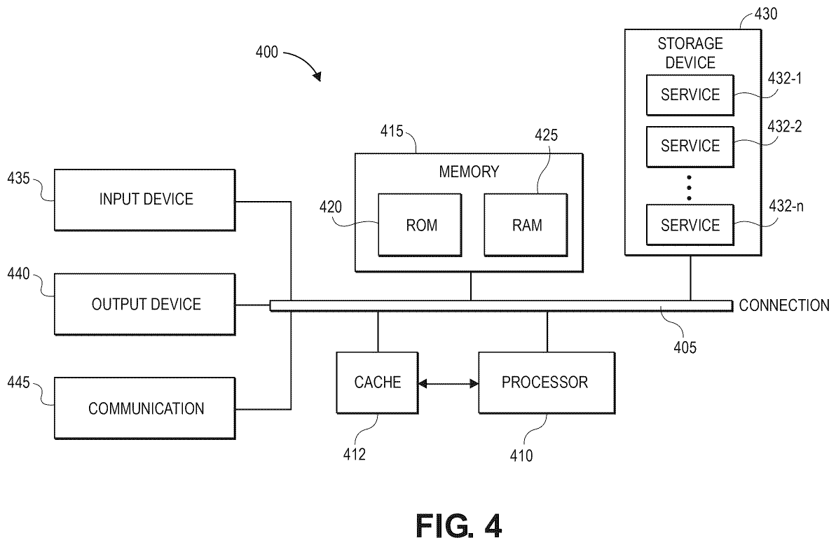

Components of computing devices or systems described herein may be arranged or configured in any number of discrete architectures. Referring to FIG. 4, a computing device architecture 400 of the present disclosure is shown. In some examples, the computing device architecture 400 may be provided on an edge computing unit, such as the edge computing apparatuses 200 of FIGS. 2A and 2B, the edge computing units 330-i, 330-1, 330-2 . . . 330-n of FIGS. 3A and 3B, or any other edge computing apparatuses or units. Alternatively, or additionally, the computing device architecture 400 may be provided on any other type or form of computing devices, such as mobile devices (e.g., smartphones, tablet computers, or the like), desktop computers, laptop computers, tablet computers, wearable devices (e.g., glasses or headsets for augmented reality or virtual reality, wrist watches, or others), servers, autonomous vehicles, robotic devices, televisions that may include one or more processors, memory components or data stores, displays, sensors, input/output (or “I/O”) devices, or other systems or components that may be configured to execute one or more sets of instructions or commands described herein.

As is shown in FIG. 4, components of the computing device architecture 400 may be in electrical communication with each other by way of a connection 405, e.g., a bus. The computing device architecture 400 shown in FIG. 4 includes a processor unit 410 (e.g., a CPU, a GPU, or another processor unit) coupled to various components of the computing device architecture 400, including but not limited to a set of memory components 415, e.g., a cache of high-speed memory connected directly with, in close proximity to, or integrated as part of the processor 410, such as read-only memory (“ROM”) 420 and random-access memory (“RAM”) 425. The processor unit 410 may be any general-purpose processor or a special-purpose processor, such as a self-contained system.

The computing device architecture 400 also includes a storage device 430 including one or more sets of data or instructions for performing various services 432-1, 432-2 . . . 432-n. The storage device 430 may be a non-volatile memory, a hard disk or another type of computer-readable media that may store data that is accessible to the computing device architecture 400 or other computers, such as magnetic cassettes, flash memory cards, solid state memory devices, digital versatile disks, cartridges, as well as the memory 415, e.g., the ROM 420, the RAM 425, and any others. One or more of the services 432-1, 432-2 . . . 432-n may be provided and executed for controlling the processor unit 410 or any other aspect of the computing device architecture 400.

The computing device architecture 400 further includes an input device 435, an output device 440 and a communications interface 445. The input device 435 enables interaction with the computing device architecture 400 and may represent any number of input mechanisms, e.g., a microphone for receiving sounds or speech signals, a touch-sensitive screen for receiving gestures or other manual inputs, or others. The output device 440 may represent any number of output mechanisms, e.g., a display, a projector, a television, a speaker device, or others. The communications interface 445 may be configured to govern or manage inputs received from users via the input device 435 and outputs to be provided to such users via the output device 440.

As used herein, the terms “device,” “system” or “unit” need not be limited to any one or a specific number of physical objects (such as one smartphone, one controller, one processing system and so on), and may instead refer to any system having any number of parts that may implement any portions of the present disclosure. Likewise, the terms “device,” “system” or “unit” are not limited to any configuration, type, or number of objects.

Devices implementing processes and methods according to these disclosures may include hardware, software, firmware, middleware, microcode, hardware description languages, or any combinations thereof, and may take any of a variety of form factors. When implemented in software, firmware, middleware, or microcode, the program code or code segments to perform the necessary tasks (e.g., a computer-program product) may be stored in a computer-readable or machine-readable medium.

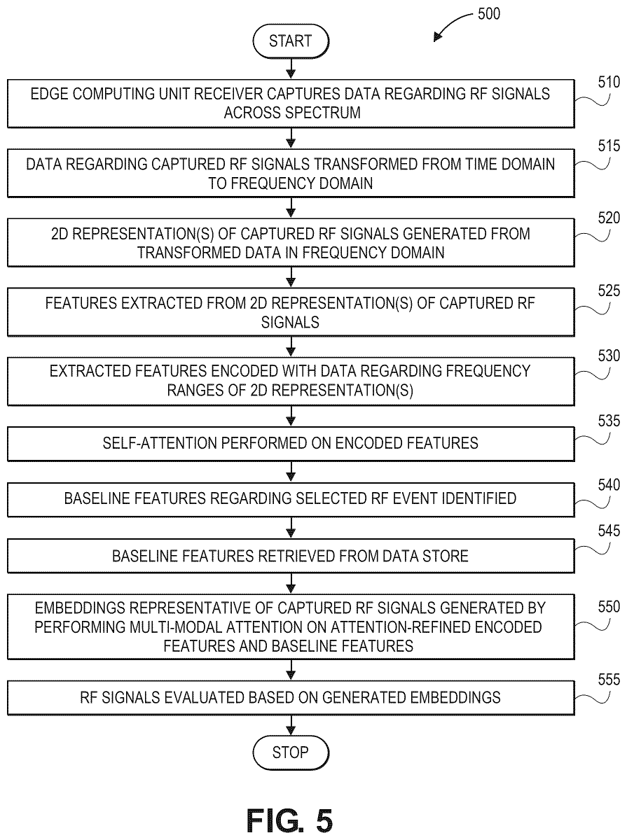

Referring to FIG. 5, a flow chart 500 of one process in accordance with implementations of the present disclosure is shown.

At box 510, an edge computing unit receiver captures RF signals across the RF spectrum. For example, the edge computing unit may be outfitted with one or more receivers for capturing RF signals at any frequency or wavelength within the RF spectrum. In some implementations, a source may emit one or more RF signals, which may be one or more radio waves in the form of pulsed RF signals or continuous-wave RF signals. One or more receivers of the edge computing unit may include one or more antennas or other features for capturing the emitted RF signals, either directly from the source, or by reflection or scattering from one or more objects.

In some implementations, the edge computing unit may be outfitted or equipped with an all-digital receiver having one or more superconductor receiving chips, as well as interface electronics and a post-processing module, which may include one or more field programmable gate arrays or other integrated circuits. Such chips may include one or more modulators or a modulation-demodulation architecture and may be paired with one or more mixers or digital filters. Receivers of the edge computing unit may be configured to directly digitize RF signals over broad frequency ranges, e.g., between about a low frequency (or “LF”) range and a very high frequency (or “VHF”) or extremely high frequency (or “EHF”) range or above, or any other frequency ranges. Additionally, the edge computing unit may be outfitted or configured with one or more data stores including rack-mounted redundant arrays of independent disks that are configured to receive and store data regarding RF signals that has been captured at extremely high rates.

In some implementations, one or more components of the edge computing unit may be cooled to extremely low temperatures, e.g., less than twenty degrees Kelvin (or less than negative 253.15 degrees Celsius), to enhance their performance in capturing RF signals across broad frequency ranges. For example, the receivers may be maintained at such temperatures using one or more features that operate using liquid nitrogen or other coolants to maintain the receivers at selected temperatures. Furthermore, in some implementations, interior portions of the edge computing unit may be maintained within selected temperature ranges or margins, and within selected pressure ranges or margins.

At box 515, data regarding the captured RF signals is transformed from a time domain to a frequency domain.

For example, in some implementations, the receivers or one or more processor units of the edge computing unit may be configured to convert the received RF signals to electromagnetic waves, and to filter, boost, amplify or otherwise process the RF signals, as necessary, to decompose the RF signals into their constituent frequencies. In a time domain, RF signals are represented as functions of time, and indicate changes in amplitudes of the signals over time. In a frequency domain, however, the RF signals are represented in terms of their frequency components, and represent amplitudes or powers of such signals at different frequencies.

The data regarding the captured RF signals may be transformed from a time domain to a frequency domain in any manner, such as according to a Fourier transform analysis, e.g., a Fast Fourier Transform analysis (or “FFT”), a discrete Fourier Transform analysis (or “DFT”), or any other transform analysis. For example, where the data is sampled at a sufficiently high rate, the data may be processed to generate a predetermined number of digital samples in the time domain, and the digital samples may be further processed, e.g., by windowing or padding, as necessary to improve the frequency resolution. The digital samples may be processed according to a Fourier Transform algorithm to generate a plurality of frequency components of the RF signals, including magnitudes (or amplitudes) and phase angles of such components in a plurality of frequency bins. In some implementations, the RF signals may be divided into one or more overlapping time windows prior to performing a Fast Fourier Transform analysis on each of such windows to determine frequency content of each of such windows.

At box 520, one or more two-dimensional representations of the captured RF signals are generated in the frequency domain. For example, once the RF signals have been converted from a time domain to a frequency domain, the magnitudes (or amplitudes) of the frequency components may be plotted with respect to frequencies in order to represent the spectral content of the captured RF signals.

The two-dimensional representations of the captured RF signals may include the frequencies shown as a function of time, such as in a waterfall plot, e.g., with frequencies along an x-axis (or horizontal axis) and time along a y-axis (or vertical axis), and with signal power or amplitude shown according to a color gradient. Over time, for example, rows of frequency data including outputs from a Fast Fourier Transform are stacked in a waterfall plot, which resembles a cascading stream of data.

At box 525, sets of features are extracted from each of the two-dimensional representations of the captured RF signals generated in the frequency domain at box 520. For example, each one of the two-dimensional representations may be processed to extract the features in the same manner as a visual image, such as by normalizing, denoising or otherwise preprocessing each of the two-dimensional representations, and identifying visual features (e.g., color features, texture features, shape features, or others), keypoints, as well as semantic features. The features may be extracted from the two-dimensional representations according to one or more convolutional neural networks, which may be fully connected and also pretrained, or other deep learning techniques. The features and may be represented as one or more maps of features, sets of features, or vectors (e.g., one-dimensional) representing the features.

At box 530, the sets of features extracted at box 525 are encoded with data regarding one or more frequency ranges. For example, the frequency ranges may correspond to ranges of the RF signals that are represented in the respective two-dimensional representations, and may be appended to portions of the sets of features to identify locations corresponding to such ranges within such portions. Alternatively, or additionally, the sets of features extracted at box 525 may be encoded with data indicating what each of the respective features represents or any relationships between the respective features.

The data regarding the one or more frequency ranges may be encoded into the set of features in any manner, such as using one or more transformer models, networks, pooling techniques, or segmentation techniques.

At box 535, self-attention is performed on the encoded features. In some implementations, self-attention may be applied to the features extracted at box 525 that have been encoded with the frequency ranges at box 530, one or more attention mechanisms that determine or weigh levels of importance of different portions of the two-dimensional representations, as encoded with frequency ranges, to one another. For example, in some implementations, attention scores may be calculated based on the encoded features to capture relationships between all of the encoded features, e.g., according to a SoftMax function or in any other manner. The encoded features may be linearly transformed according to one or more learned weight matrices, and the transformed features may be used to calculate the attention scores.

In some implementations, the self-attention may be performed using a single head or multiple heads. For example, in some implementations, a transformer model may perform self-attention on the encoded features using a single set of query inputs, key inputs or value inputs. In some other implementations, however, a transformer model may perform self-attention on encoded features using multiple subspaces of query inputs, key inputs and value inputs, in order to consider different (e.g., long-range) behavior represented in the encoded features by the same attention mechanism, and to perform attention pooling in parallel, such as where each of the outputs is called a “head,” and may be concatenated and linearly transformed.

At box 540, baseline features associated with selected RF events are identified. For example, where information or data regarding a plurality of RF events during which RF signals of various frequencies or power levels were transmitted and received is known, the RF signals and any other information or data associated with each of such RF events may be processed, according to actions or functions described in connection with one or more of boxes 515 through 535. For example, data regarding the RF signals may be transformed from a time domain to a frequency domain, two-dimensional representations of the captured signals in the frequency domain may be generated, and features may be extracted from the two-dimensional representations. Additionally, where additional information or data regarding the RF events is known, such as identifiers of sources of the RF signals, or types, forms or classes of such sources, the information or data regarding the RF events may also be processed to extract features from such information or data. The extracted features may be further encoded with data regarding frequency ranges of such representations, and self-attention may be performed on the encoded features.

The baseline features may be extracted and otherwise processed in real time or near-real time, in one or more batch processes, or in any other manner. For example, in some implementations, baseline features may be extracted from two-dimensional representations of RF signals that were actually captured during RF events, e.g., by a receiver of the edge computing unit or another system, at an earlier time along with any information or data regarding the RF events. In some other implementations, however, baseline features may be extracted from two-dimensional representations of RF signals that are synthesized based on information or data that is known regarding one or more RF signals, RF sources or RF events, e.g., frequencies and powers or intensities of the RF signals that are to be emitted by the RF sources during the RF events over time.

The baseline features may be stored in association with any information or data regarding the RF signals, the RF sources or the RF events, including identifiers of the frequencies, pulse rates, or other information or data regarding such RF signals, such RF sources or such RF events, as well as identifiers of devices, systems or components that are known or believed to emit such RF signals, or entities associated with such devices, systems or components.

For example, where an RF event includes an emission of signals by a communication device (e.g., a mobile telephone, a Walkie-Talkie, or a wireless router), baseline features may be generated based on RF signals emitted during the RF event as well as identifiers of the RF signals or the communication device, a category in which the communication device is included (e.g., personal or government-operated), or any information, data or metadata regarding the RF event, such a date or a time of the RF event, a location at which the RF signals of the RF event were captured, or a purpose or reason for the RF event (e.g., initiating communication, responding to communication, or others), where the purpose or the reason is known. Alternatively, or additionally, the baseline features may be generated based on dates or times at which the RF event is known or likely to occur, or locations at which the RF event is likely to be observed. Likewise, as another example, where an RF event includes an emission of signals by a radar system, baseline features may be generated based on RF signals emitted during the RF event as well as identifiers of the RF signals or the radar system, a category in which the radar system is included (e.g., airborne or ground-based radar, civilian or military, or the like), or any information, data or metadata regarding the RF event, such a date or a time of the RF event, a location at which the RF signals of the RF event were captured, or a purpose or reason for the RF event (e.g., searching, tracking, or others) where the purpose or the reason is known.

At box 545, the baseline features identified at box 540 are retrieved from one or more data stores. For example, in some implementations, the baseline features may be stored in one or more data stores provided on the edge computing unit. Alternatively, the baseline features may be stored on one or more data stores provided on any other computing unit or system, and may be retrieved therefrom by the edge computing unit over one or more networks.

At box 550, embeddings representative of the captured RF signals are generated by performing multi-modal attention on the attention-refined encoded features following the self-attention at box 535 and the baseline features retrieved at box 545. For example, in some implementations, the baseline features retrieved at box 545 may be provided as a query input, while the encoded features following performance of self-attention at box 535 may be provided as a key input and a value input, and portions of the two-dimensional representations of the RF signals captured at box 510 that are deemed most relevant to the two-dimensional representations of RF signals emitted during selected RF events identified at box 540 may be determined and represented in the embeddings generated at box 550.

At box 555, the RF signals are evaluated based on the generated embeddings, and the process ends. For example, a decoder or another component of a transformer model may decode the embeddings generated at box 550 in order to characterize the RF signals captured at box 510 with respect to the selected RF events, to identify or classify a source of the RF signals, or a type, form or class of the source, as well as to determine a location of the source, to determine whether the RF signals or the RF events have been previously encountered in the location, or to determine whether the RF signals or the RF events are unprecedented or unexpected in the location. The embeddings may be further decoded to predict whether any other events or occurrences may be anticipated, based on the RF event. In some implementations, the embeddings may be passed through a feed-forward network and normalized before one or more sets of probabilities are generated based on the embeddings. Moreover, one or more confidence levels or confidence scores associated with a determination or a classification of a source, an RF event, an RF source or RF signals may be calculated in accordance with implementations of the present disclosure.

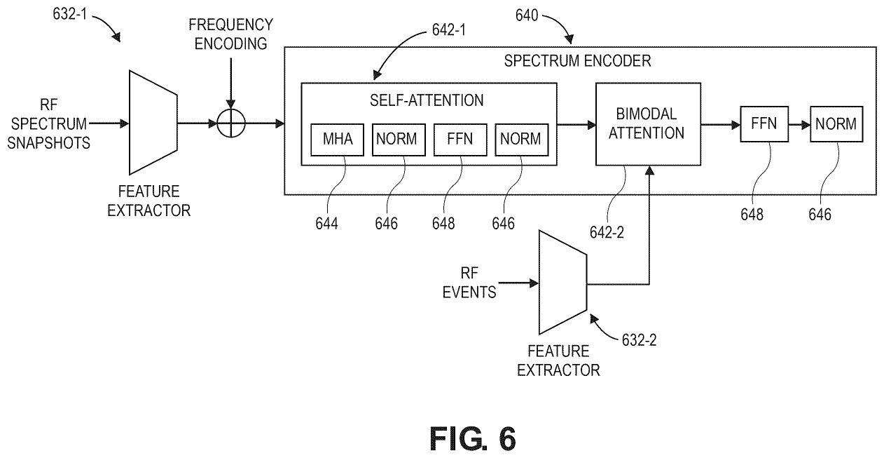

As is discussed above, a machine learning model (or an algorithm, a system or a technique) may include one or more components or features for generating embeddings representative of RF signals captured by a receiver. Referring to FIG. 6, a view of aspects of one system in accordance with embodiments of the present disclosure is shown.

As is shown in FIG. 6, a spectrum encoder 640 is configured to receive inputs in the form of sets of features generated by a feature extractor 632-1 from two-dimensional representations (e.g., snapshots) of captured RF signals that have been encoded with frequency ranges of the RF signals, and sets of features generated by a feature extractor 632-2 based on representations of RF signals emitted during discrete RF events. The spectrum encoder 640 includes a self-attention module 642-1 having a multi-head attention element 644, normalization layers 646 and a feedforward network 648. Encoded features extracted from the two-dimensional representations of the captured RF signals are provided to the self-attention module 642-1, and outputs from the self-attention module 642-1, including a set of embeddings, are provided to a multi-modal (e.g., a bimodal) attention module 642-2 along with features generated by the feature extraction module 632-2 from the representations of the discrete RF signals.

Outputs received from the bimodal attention module 642-2 in the form of embeddings are provided to another feedforward network 648, and another normalization layer 646. Following normalization by the final normalization layer 646, an output from the spectrum encoder 640 may be decoded to determine whether the two-dimensional representations of the captured RF signals are consistent with any of the two-dimensional representations of any of the discrete RF events, and to classify the captured RF signals accordingly.

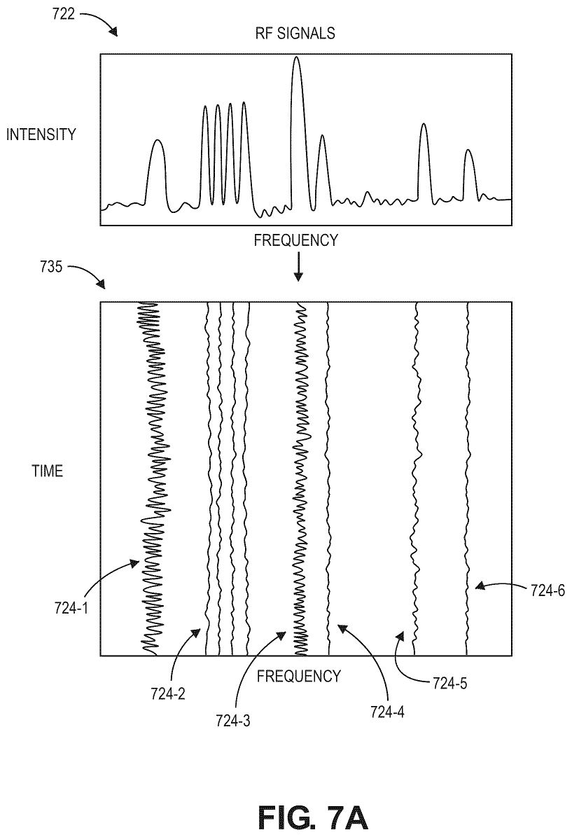

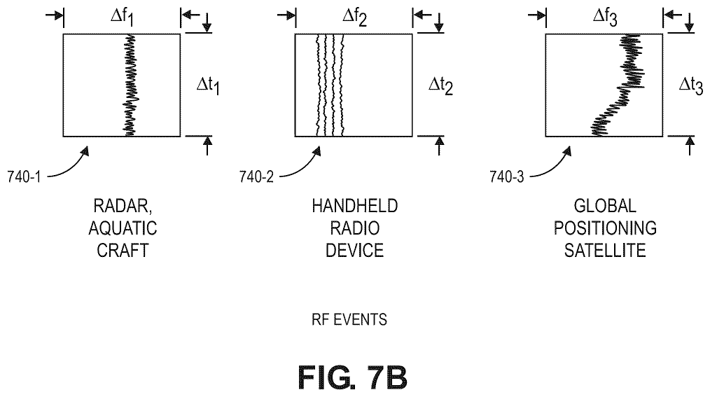

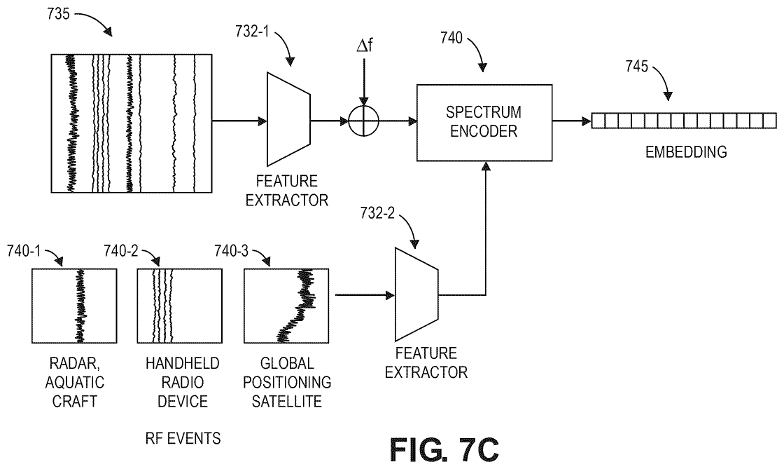

Referring to FIGS. 7A through 7C, views of aspects of one system in accordance with embodiments of the present disclosure are shown. As is shown in FIG. 7A, data 722 regarding a plurality of RF signals captured in a time domain is transformed to a frequency domain, e.g., by a Fast Fourier Transform technique, and a spectrogram 735, or another two-dimensional representation, is generated based on the data 722. Where the data 722 identifies intensities of a plurality of signals over a broad range of frequencies, the spectrogram 735 includes plots 724-1, 724-2, 724-3, 724-4, 724-5, 724-6 of the captured RF signals in a waterfall plot, e.g., with frequencies along an x-axis (or horizontal axis) and time along a y-axis (or vertical axis), and powers or amplitudes of the captured RF signals shown according to a color gradient. In particular, the spectrogram 735 includes rows of frequency data stacked in a waterfall plot, and visibly indicates the high-intensity RF signals represented in the data 722 at each time.

As is shown in FIG. 7B, a plurality of discrete RF events 740-1, 740-2, 740-3 including two-dimensional representations of signal emissions in selected frequency ranges by a set of sources over periods of time are shown. For example, the RF event 740-1 includes emissions of radar signals by an aquatic craft in a range Δf₁ of frequencies over a period of time Δt₁, while the RF event 740-2 includes emissions of communication signals by a handheld device a range Δf₂ of frequencies over a period of time Δt₂, and the RF event 740-3 includes emissions of position signals by a global positioning satellite in a range Δf₃ of frequencies over a period of time Δt₃.

As is shown in FIG. 7C, the spectrogram 735 is provided as an input to a feature extractor 732-1, and outputs from the feature extractor 732-1, e.g., a set of features representative of the plots 724-1, 724-2, 724-3, 724-4, 724-5, 724-6, are encoded with a frequency range of the plots 724-1, 724-2, 724-3, 724-4, 724-5, 724-6 and provided with sets of features representative of the two-dimensional representations 740-1, 740-2, 740-3 of the RF events to a spectrum encoder 740 of the present disclosure. Outputs of the spectrum encoder 740 may include one or more embeddings 745, which may be decoded to determine whether any of the RF events represented in the two-dimensional representations 740-1, 740-2, 740-3 are present within the spectrogram 735.

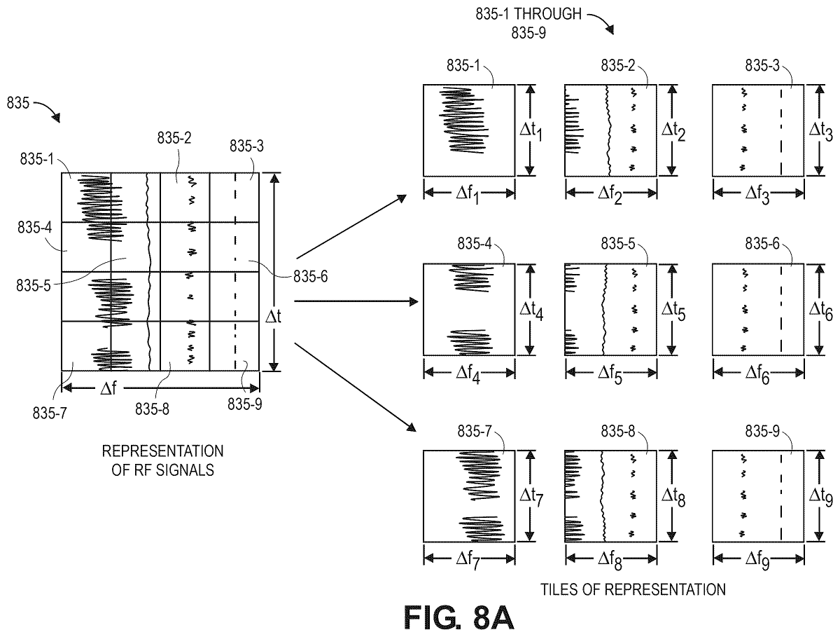

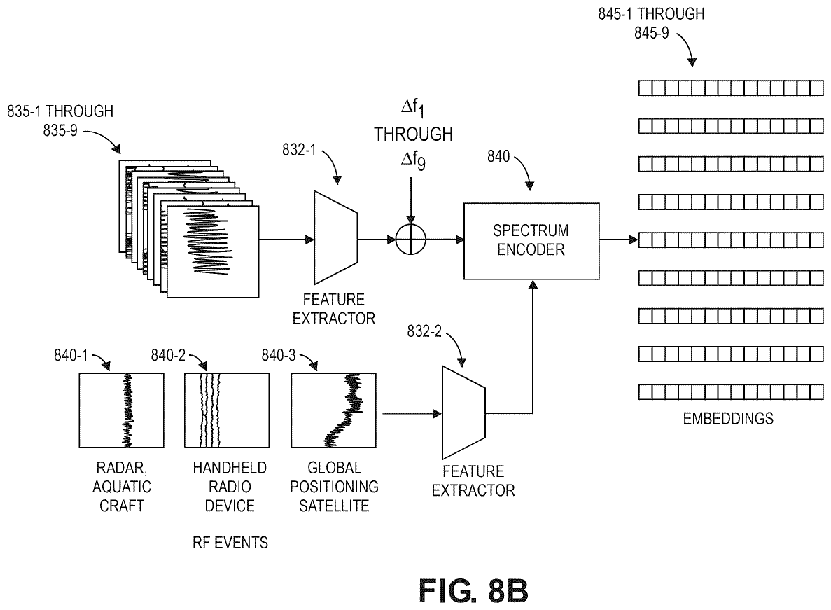

In some implementations, where a set of RF signals is captured and a spectrogram or another two-dimensional representation is generated from data representing the RF signals, the spectrogram may be divided into tiles or other portions or subsets, which may be independently encoded with frequency ranges and processed to determine whether such tiles depict any selected RF events. Referring to FIGS. 8A and 8B, views of aspects of one system in accordance with embodiments of the present disclosure are shown. As is shown in FIG. 8A, a spectrogram 835 or another two-dimensional representation of captured RF signals in a frequency domain covering a frequency range Δf and a duration Δt is divided into a plurality of tiles 835-1 through 835-9, each having a frequency range Δf₁, Δf₂, Δf₃, Δf₄, Δf₅, Δf₆, Δf₇, Δf₈, Δf₉ and a duration Δt₁, Δt₂, Δt₃, Δt₄, Δt₅, Δt₆, Δt₇, Δt₈, Δt₉, respectively. The frequency ranges Δf₁ through Δf₉ of the tiles 835-1 through 835-9 cover the entire frequency range Δf of the spectrogram 835 and the durations Δt₁ through Δt₉ of the tiles 835-1 through 835-9 cover an entire duration Δt of the spectrogram 835. For example, each of the tiles 835-1 through 835-9 may be homogenous in nature, such that each of the frequency ranges Δf₁ through Δf₉ of the tiles 835-1 through 835-9 has a common width and each of the durations Δt₁ through Δt₉ of the tiles 835-1 through 835-9 has a common duration. Alternatively, two or more of the frequency ranges Δf₁ through Δf₉ of the tiles 835-1 through 835-9 may have different widths, or two or more of the durations Δt₁ through Δt₉ may be different.

Additionally, in some implementations, the tiles 835-1 through 835-9 may cover adjacent frequency ranges or adjacent durations, such that one of the frequency ranges Δf₁ through Δf₉ ends when another of the frequency ranges Δf₁ through Δf₉ begins, or one of the durations Δt₁ through Δt₉ ends when one of the durations Δt₁ through Δt₉ begins. Alternatively, as is shown in FIG. 8A, the tiles 835-1 through 835-9 may overlap, to ensure that each aspect of the frequency range Δf of the spectrogram 835, or each portion of the duration Δt of the spectrogram 835, is covered by at least one of the tiles 835-1 through 835-9.

As is shown in FIG. 8B, each of the tiles 835-1 through 835-9 are processed by a feature extractor 832-1 to extract features therefrom and encoded with their respective frequency ranges Δf₁ through Δf₉. Additionally, a plurality of representations 840-1, 840-2, 840-3 of RF signals emitted during RF events are processed by a feature extractor 832-2 to extract features therefrom. The encoded features extracted from the respective tiles and the features extracted from the representations are provided as inputs to a spectrum encoder 840, which generates a set of embeddings 845-1 through 845-9 that may be decoded to determine whether any RF signals represented in each of the respective tiles 835-1 through 835-9 is consistent with any of the RF signals of any of the RF events depicted in the representations 840-1, 840-2, 840-3.

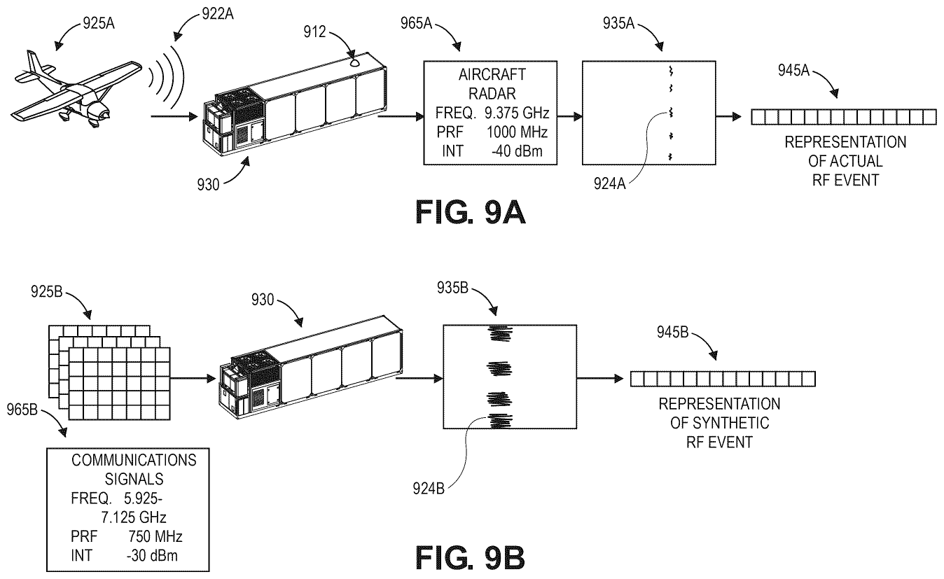

Representations of RF signals that are associated with RF events may be generated based on RF signals that are actually captured during an RF event, or based on RF signals that are synthetically captured during an RF event. Referring to FIGS. 9A and 9B, views of aspects of one system in accordance with embodiments of the present disclosure are shown.

As is shown in FIG. 9A, where an RF event includes an emission of RF signals 922A by a known source 925A, e.g., a private aircraft, the RF signals 922A may be captured by a receiver 912 of an edge computing unit 930. Information 965A regarding the RF signals 922A and the source 925A may be determined and stored in association with the RF signals 922A and the source 925A in one or more data stores. For example, the information 965A may identify the source 925A or a category or group of which the source 925A is a member, as well as any relevant information or data regarding the RF signals 922A, such as a frequency of the RF signals 922A, a pulse repetition frequency of the RF signals 922A, or an intensity or strength of the RF signals 922A. Based on the RF signals 922A, a spectrogram 935A or another two-dimensional representation including a plot 924A of the RF signals 922A may be generated, and processed, e.g., by a spectrum encoder, to generate an embedding 945A representative of the spectrogram 935A. The embedding 945A may be stored in association with the information 965A, or any other information or data regarding the source 925A or the RF signals 922A, in one or more data stores and utilized for any purpose.

Alternatively, as is shown in FIG. 9B, where data 925B regarding RF signals or a source of the RF signals is known, information 965B regarding the RF signals or the source may be determined from the data 925B. The information 965B may include but need not be limited to a type or category of the RF signals, as well as a frequency, a pulse repetition frequency, and an intensity of the RF signals. Subsequently, the edge computing unit 930 (or another computing device or system) may process the data 925B regarding the RF signals to generate a spectrogram 935B or another two-dimensional representation including a plot 924B of the RF signals. The spectrogram 935B may be processed to generate an embedding 945B representative of the spectrogram 935B, which may be stored in association with the information 965B, or any other data 925B regarding the source or the RF signals, in one or more data stores and utilized for any purpose.

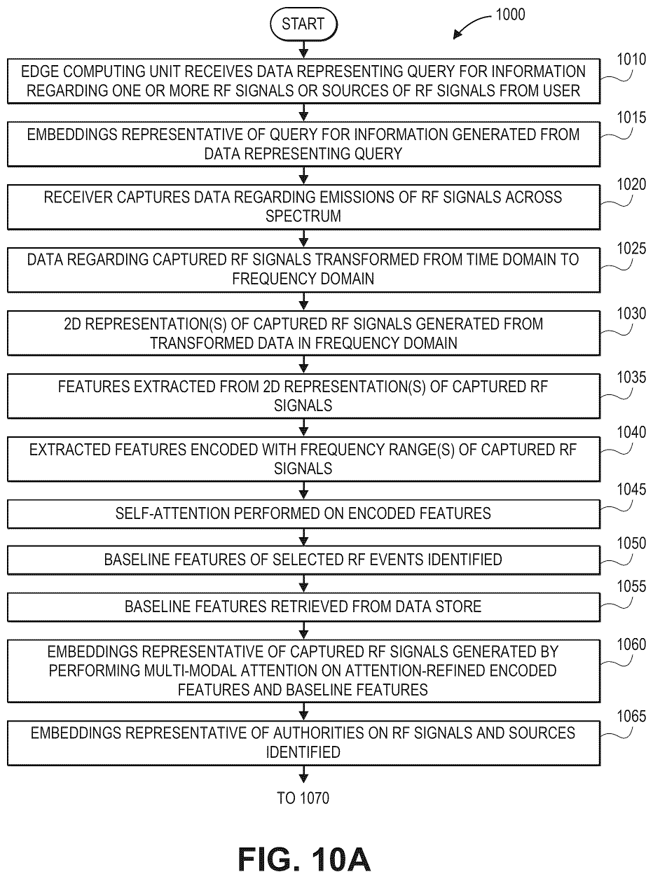

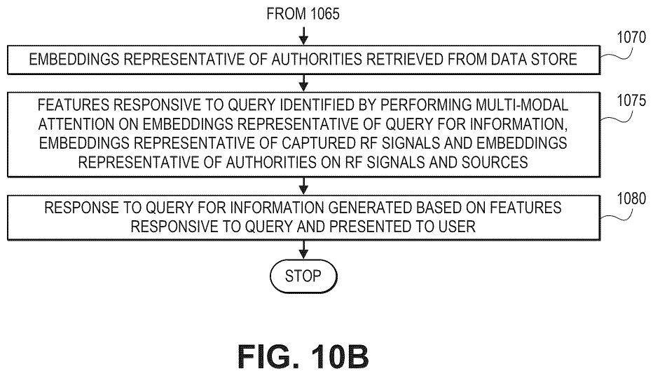

As is discussed above, embeddings generated by spectrum encoders of the present disclosure based on emissions of RF signals by RF sources may be decoded to identify responses to queries for information regarding such signals or such sources. Referring to FIGS. 10A and 10B, a flow chart 1000 of one process in accordance with implementations of the present disclosure is shown.

At box 1010, an edge computing unit receives data representing a query for information regarding one or more RF signals or one or more sources of RF signals from a user. The edge computing unit may receive the query for information from the user in any manner. In some implementations, the query for information may be a text-based query provided by the user using one or more textual commands entered into a terminal or a search box. The text-based query may be processed by one or more natural language processing (or “NLP”) algorithms, systems or techniques and provided to the edge computing unit via one or more application programming interfaces, e.g., a programmatic query made in one or more payloads or files in a format such as JSON or XML, or in accordance with one or more scripts. Alternatively, the query for information may be a voice-based query including one or more utterances of spoken or sung words to a virtual assistant that are processed by one or more speech recognition systems. In still other implementations, the user may make one or more queries by way of features of a graphical user interface, such as a form, a search box, a drop-down menu, one or more buttons, or dashboards.

In some other implementations, the query for information may be made by one or more gestures, such as touchscreen interactions or motion-based gestures, or interactions with one or more touchless interfaces. Alternatively, the user may provide the query of information in any other manner in accordance with implementations of the present disclosure.

At box 1015, one or more embeddings representative of the query for information are generated based on the data received at box 1010. For example, the query may be tokenized, and each token may be mapped to one or more vectors using an embedding matrix or in any other manner. One or more positional encodings may be added to such tokens to indicate their respective positions within a sequence of the tokens, and contextual embeddings may be generated based on the encodings to represent meanings of words of the query, relationships between the words, and a global context of the query.

At box 1020, a receiver captures data regarding emissions of RF signals across the RF spectrum. For example, a receiver may capture RF signals at any frequency or wavelength, in the form of radio waves (e.g., pulsed or continuous-wave signals). The receiver may be an all-digital receiver provided in an edge computing unit, or any other type of receiver that may be associated with any other type or form of system, other than an edge computing unit.

At box 1025, data regarding the captured RF signals is transformed from the time domain to a frequency domain. For example, the data may be pre-processed or processed, as necessary, before being subjected to a Fourier transform, e.g., a Fast Fourier Transform algorithm to generate a plurality of frequency components of the RF signals, including magnitudes (or amplitudes) and phase angles of such components in a plurality of frequency bins. In some implementations, the RF signals may be divided into one or more overlapping time windows prior to performing a Fast Fourier Transform analysis on each of such windows to determine frequency content of each of such windows.

At box 1030, one or more two-dimensional representations of the captured RF signals are generated from the transformed data in the frequency domain. The two-dimensional representations of the captured RF signals may depict frequencies as a function of time, e.g., in a waterfall plot with frequencies along an x-axis (or horizontal axis) and time along a y-axis (or vertical axis), and with signal power or amplitude shown according to a color gradient. The two-dimensional representations may include rows of frequency data stacked in a waterfall plot, which may resemble a cascading stream of data.

At box 1035, features are extracted from the two-dimensional representations of the captured RF signals. For example, the two-dimensional representations may be processed in the same manner as a visual image, such as by normalizing, denoising or otherwise preprocessing each of the two-dimensional representations, and identifying visual features (e.g., color features, texture features, shape features, or others), keypoints, as well as semantic features from such images. The features may be extracted from the two-dimensional representations using one or more convolutional neural networks, which may be fully connected and also pretrained, or other deep learning techniques, and may be represented as one or more maps, sets or vectors of such features.

At box 1040, the features extracted from the two-dimensional representations of the captured RF signals are encoded with frequency ranges associated with the captured RF signals. The frequency ranges may correspond to ranges of the RF signals that are represented in the respective two-dimensional representations, and may be appended to portions of the sets of features to identify locations corresponding to such ranges within such portions. Alternatively, or additionally, the extracted features may be encoded with data indicating what each of the respective features represents or any relationships between the respective features. The extracted features may be encoded with the frequency ranges in any manner.

At box 1045, self-attention is performed on the encoded features. For example, in some implementations, attention scores may be calculated based on the encoded features to capture relationships between all of the encoded features, e.g., according to a SoftMax function or in any other manner.

At box 1050, baseline features of selected RF events are identified. For example, the baseline features may have been generated based on RF events that were previously observed or detected, or on RF signals that were captured on a previous date or at a previous time, and transformed to a frequency domain. The baseline features may have been extracted from two-dimensional representations of the RF signals in the frequency domain, as well as any other information or data regarding the RF events, such as identifiers of frequencies, pulse rates, or other information or data regarding such RF signals or such RF events, as well as identifiers of devices, systems or components that are known or believed to emit such RF signals, or entities associated with such devices, systems or components. The baseline features may also be encoded with data regarding frequency ranges of such representations. Additionally, the baseline features may be stored in association with any information or data regarding the RF signals or the RF events

At box 1055, the baseline features identified at box 1050 are retrieved from one or more data stores.

At box 1060, a set of embeddings representative of the captured RF signals is generated by performing multi-modal attention on the attention-refined encoded features, the baseline features and the features representative of the query for information. The baseline features retrieved at box 1055 may be provided as a query input, while the encoded features following performance of self-attention at box 1045 may be provided as a key input and a value input, and portions of the two-dimensional representations of the RF signals captured at box 1020 that are deemed most relevant to the two-dimensional representations of RF signals emitted during selected RF events identified at box 1040 may be determined and represented in the embeddings.

At box 1065, a set of embeddings representative of authorities on RF signals and sources of RF signals is identified, and at box 1070, the set of embeddings representative of authorities on RF signals and sources of RF signals is retrieved from one or more data stores. For example, the set of embeddings may have been generated based on any type or form of literature regarding RF signals or sources of the RF signals, such as technical manuals, guides, standards, regulations, handbooks, textbooks, data sheets, reports, white papers, journals, data or other resources. The set of embeddings may be stored on an edge computing unit or another system associated with a receiver that captured the RF signals of the RF event at box 1020. Alternatively, the set of embeddings may be stored on one or more data stores provided on any other computing unit or system, and may be retrieved therefrom over one or more networks.

At box 1075, features responsive to the query are generated by performing multi-modal attention on the embeddings representative of the query for information generated at box 1015, the embeddings representative of the captured RF signals generated at box 1060 and the embeddings representative of the authorities on RF signals and RF sources generated at box 1070.

At box 1080, a response to the query for information is generated based on the features responsive to the query and presented to the user, and the process ends.

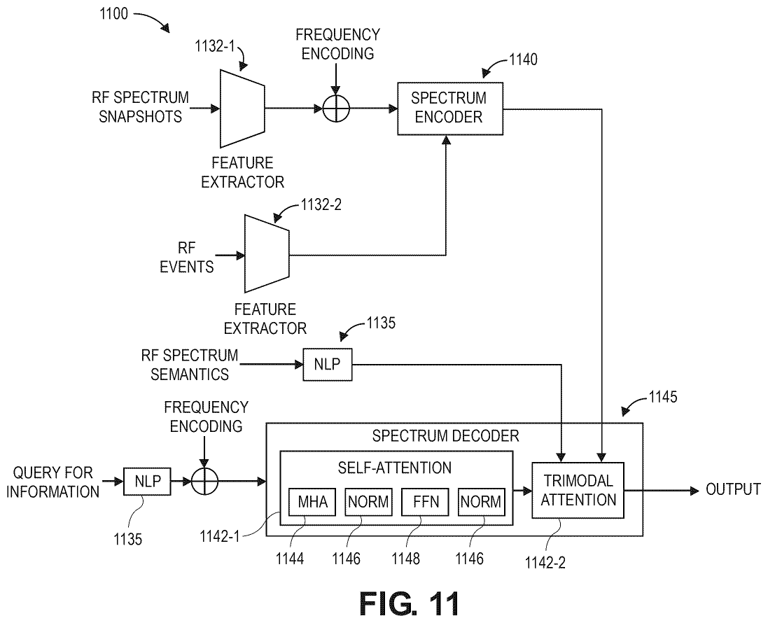

Referring to FIG. 11, a view of aspects of one system in accordance with embodiments of the present disclosure is shown. As is shown in FIG. 11, a transformer model 1100 (or another machine learning algorithm, system or technique) includes a spectrum encoder 1140 and a spectrum decoder 1145. The spectrum encoder 1140 is configured to receive inputs in the form of sets of features generated by a feature extractor 1132-1 from two-dimensional representations (e.g., snapshots) of captured RF signals that have been encoded with frequency ranges of the RF signals, and sets of features generated by a feature extractor 1132-2 based on representations of RF signals emitted during discrete RF events, such as is described above with regard to the spectrum encoder 640 of FIG. 6. For example, the spectrum encoder 1140 may include a self-attention module, which may have a multi-head attention element, and one or more normalization layers or feedforward networks. The spectrum encoder 1140 may generate embeddings representative of the RF signals represented in the encoded features, in view of the features extracted from spectrograms or other two-dimensional representations of the RF events.

As is also shown in FIG. 11, any type of semantic information may be provided as inputs to a natural language processing module 1135 (or a natural language understanding model). The semantic information may include, but need not be limited to, any literature regarding RF signals or sources of the RF signals, such as technical manuals, guides, standards, regulations, handbooks, textbooks, data sheets, reports, white papers, journals, data or other resources. The natural language processing module 1135 may generate one or more embeddings or other sets of data regarding the semantic information as outputs in response to such inputs.

The natural language processing module 1135 may tokenize the semantic information, lemmatize or stem one or more words represented in the semantic information, tag parts of speech, and recognize any entities represented therein. The natural language processing module 1135 may further determine sentiments of the semantic information, classify and summarize text of the semantic information, extract any keywords from the semantic information, model any language or topics of the semantic information, resolve any co-references in the semantic information, and translate the semantic information or otherwise correct any errors in spelling or grammar in the semantic information.

Additionally, a query for information may be provided as an input to a natural language processing module 1135, and outputs from the natural language processing module 1135 generated in response to such inputs may be encoded with data regarding a frequency range of the spectrogram or the other two-dimensional representation from which the features were extracted therefrom by the feature extractor module 1132-1. The encoded embeddings or other outputs may be provided to the spectrum decoder 1145, which may also include a self-attention module 1142-1 having a multi-head attention element 1144, normalization layers 1146 and a feedforward network 1148. Outputs from the self-attention module 1142-1, which may include a set of embeddings, are provided to a multi-modal (e.g., a bimodal) attention module 1142-2 along with embeddings generated by the spectrum encoder 1140 and the embeddings generated based on the semantic information by the natural language processing module 1135.

Outputs received from the multi-modal attention module 1142-2 in the form of embeddings are provided to another feedforward network 1148, and another normalization layer 1146. Following normalization by the final normalization layer 1146, an output from the spectrum decoder 1145 may include a set of text responsive to the query for information, which may then be presented to a user that provided the query for information, or another person, in any manner. For example, data representing the output from the spectrum decoder 1145 may be transmitted to one or more output devices, such as a display, a projector, a television, a set of headphones, a speaker device, or others, which may interpret the data and display or play aloud the output from the spectrum decoder 1145.

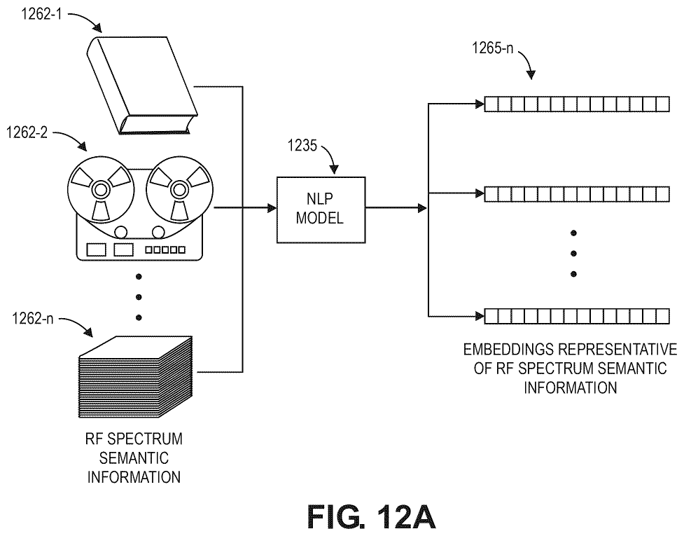

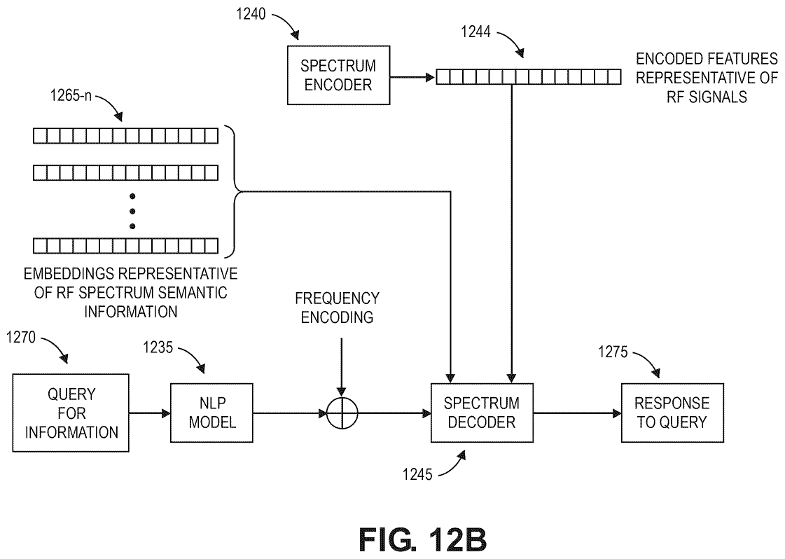

Referring to FIGS. 12A and 12B, views of aspects of one system in accordance with embodiments of the present disclosure are shown. As is shown in FIG. 12A, a plurality of semantic resources 1262-1, 1262-2 . . . 1262-n are provided as inputs to a natural language processing model 1235 (or a natural language understanding model). The semantic resources 1262-1, 1262-2 . . . 1262-n may be books or other sets of words or text, recordings of audio data or video data, contents of one or more databases, or any other authorities or resources of information or data. The natural language processing model 1235 may tokenize each of the semantic resources 1262-1, 1262-2 . . . 1262-n, or otherwise process the semantic resources 1262-1, 1262-2 . . . 1262-n, to determine content of the semantic resources 1262-1, 1262-2 . . . 1262-n, to classify the content of the semantic resources 1262-1, 1262-2 . . . 1262-n, or to otherwise model or translate the semantic resources 1262-1, 1262-2 . . . 1262-n, to generate a set of embeddings 1265-n representative of the resources 1262-1, 1262-2 . . . 1262-n accordingly.

As is shown in FIG. 12B, when a query for information 1270 is received from a computer device or system, the query for information 1270 may also be processed by a natural language processing (or natural language understanding) model 1235 and encoded with information or data regarding one or more frequency ranges to generate a set of features representative of the query for information 1270. Additionally, the query for information 1270 may be received in any manner, such as in data representing one or more typed sets of words or in audio data representing one or more spoken words, or in any other manner.

As is further shown in FIG. 12B, a spectrum decoder 1245 may receive the set of features generated by the natural language processing model 1235 based on the query for information 1270, as well as a set of features 1244 generated by a spectrum encoder 1240 and the set of embeddings 1265-n representative of the resources 1262-1, 1262-2 . . . 1262-n. The set of features 1244 may be generated by performing attention on features generated from a spectrogram or another two-dimensional representation of information or data regarding RF signals captured by a signal receiver, as well as features generated from spectrograms or other two-dimensional representations of information or data regarding RF signals associated with one or more RF events. The spectrum encoder 1240 may have one or more attributes in common with the spectrum encoder 640 of FIG. 6 and described above.

The spectrum decoder 1245 may generate a response 1275 to the query for information 1270 in the form of one or more sets of text that may be returned to a computer device or system from which the query for information 1270 was received, or another computer device or system, and caused to be displayed or played aloud to a user of the computer device or system. For example, data representing the response 1275 may be transmitted to a device or system and rendered on a display or played by one or more speakers of the device or system.

The query for information 1270 may be a request for any information or data regarding any RF signals that may have been captured, or any sources of the RF signals. For example, in some implementations, the query for information 1270 may be a direct or a specific request for information as to whether a specific RF signal (e.g., a signal at a specific frequency or a specific intensity, or within a range of frequencies or a range of intensities) was received, whether a type of RF signals was received (e.g., a communications signal, a radar signal, or any other signals), or whether any RF signals have been received from a specific source, or a source in a specific category of sources (e.g., communications signals from one of a plurality of types of sources, radar signals from one of a plurality of types of sensors, or the like).

For example, the query for information 1270 may include direct instructions such as, “tell me whether any VHF signals have been captured,” “describe all X-band signals that have been captured,” or “identify sources of all signals having intensities above negative twenty decibel-milliwatts.” The query for information 1270 may also include one or more general questions, such as, “have any weather radar signals been received?” or specific questions such as, “are any communications signals received from any water vessels?” Alternatively, the query for information 1270 may be conditional in nature, and may include instructions such as “inform me when you detect any navigation radars” or “send a notification when a communications signal or a radar signal indicating that an aircraft is within two nautical miles is received.” Similarly, the query for information 1270 may include a request for a direct conclusion regarding a source or a signal, such as, “is the RF signal from a civilian source or a military source?” or “is that RF signal expected in this location?” The query for information 1270 may also include a request for potential identifiers of sources, such as “what countries typically use components that transmit those RF signals?”

The query for information 1270 may further include a request for a prediction based on a source or a signal, such as “is the source preparing to land?” or “is the source preparing to launch a weapon?” The query for information 1270 may also be a compound query, such as “what [types of systems] from [a specific country] transmit RF signals at that frequency for [a specific purpose]?” The query for information 1270 may further request a level of confidence in a conclusion or a prediction, such as, “how confident are you in the determination that the source of RF signal is a [type of system] from [a specific country]?”

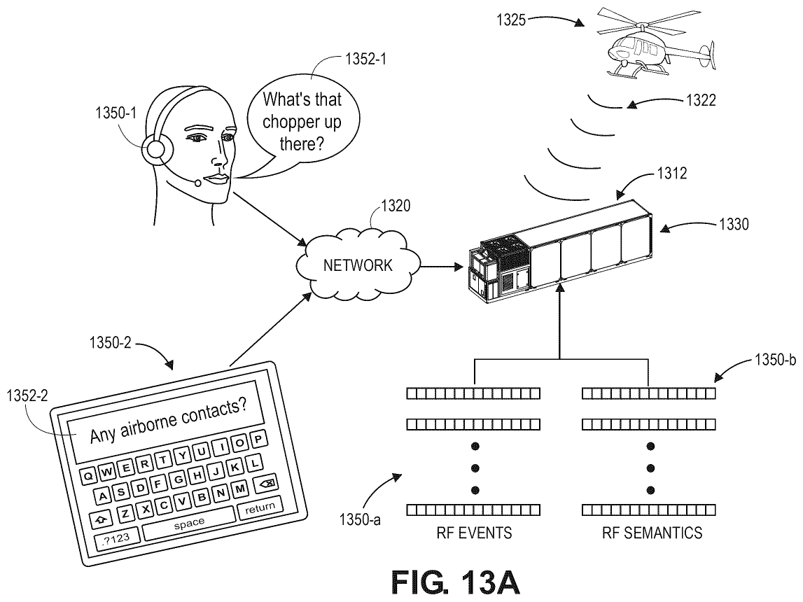

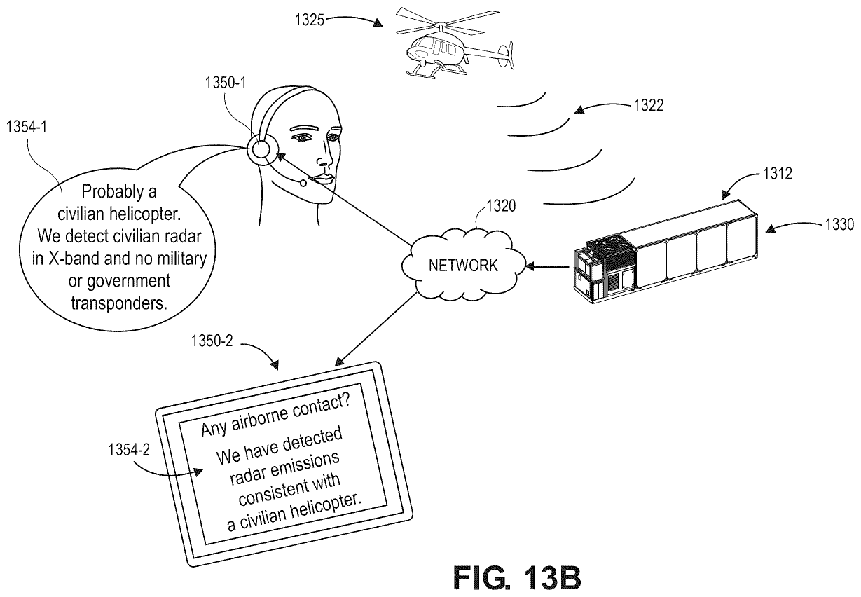

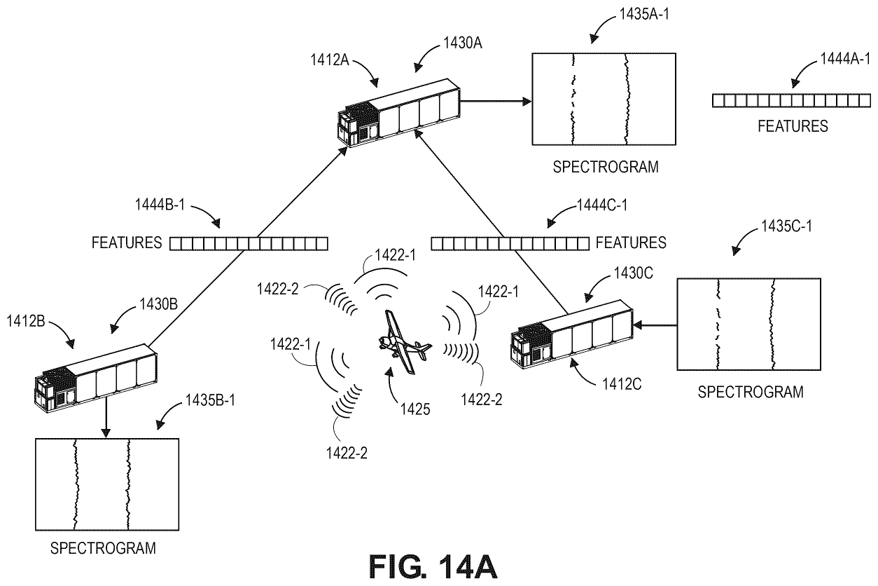

Referring to FIGS. 13A and 13B, views of aspects of one system in accordance with embodiments of the present disclosure are shown. As is shown in FIG. 13A, an edge computing unit 1330 receives queries for information 1352-1, 1352-2 from personal devices 1350-1, 1350-2 over one or more networks 1320, as a helicopter 1325 emitting RF signals 1322 flies overhead. The queries for information 1352-1, 1352-2 relate to the helicopter 1325, and include a query for information 1352-1 in the form of a set of spoken words captured by the personal device 1350-1, viz., “What's that chopper up there?” and a query for information 1352-2 in the form of a set of typed words received by the personal device 1350-2, viz., “Any airborne contacts?” In accordance with implementations of the present disclosure, the edge computing unit 1330 has access to a plurality of embeddings 1350-a representative of RF events, which may have been extracted from spectrograms or other two-dimensional representations of RF signals captured during the RF events, as well as a plurality of embeddings 1350-b representative of semantic information regarding RF signals or sources of RF signals, which may have been generated by providing the semantic information to a natural language processing (or natural language understanding) model operated by the edge computing unit 1330, or another computer device or system in communication with the edge computing unit 1330.

As is shown in FIG. 13B, the edge computing unit 1330 generates responses 1354-1, 1354-2 to the queries for information 1352-1, 1352-2, and transmits data representing the responses 1354-1, 1354-2 to the personal devices 1350-1, 1350-2. For example, as is shown in FIG. 13B, the response 1354-1 to the query for information 1352-1 includes a set of words generated based on an output of a spectrum decoder of a transformer model executed by the edge computing unit 1330, viz., “Probably a civilian helicopter. We detect civilian radar in X-band and no military or government transponders.” Likewise, as is also shown in FIG. 13B, the response 1354-2 to the query for information 1352-2 includes a set of words generated based on an output of the spectrum decoder, viz., “We have detected radar emissions consistent with a civilian helicopter.” Alternatively, or additionally, the responses 1354-1, 1354-2 may include any other information or data regarding the signals 1322 identified in response to the queries for information 1352-1, 1352-2, as well as any other information or data that may provide additional context or background regarding the queries for information 1352-1, 1352-2 or the responses 1354-1, 1354-2.

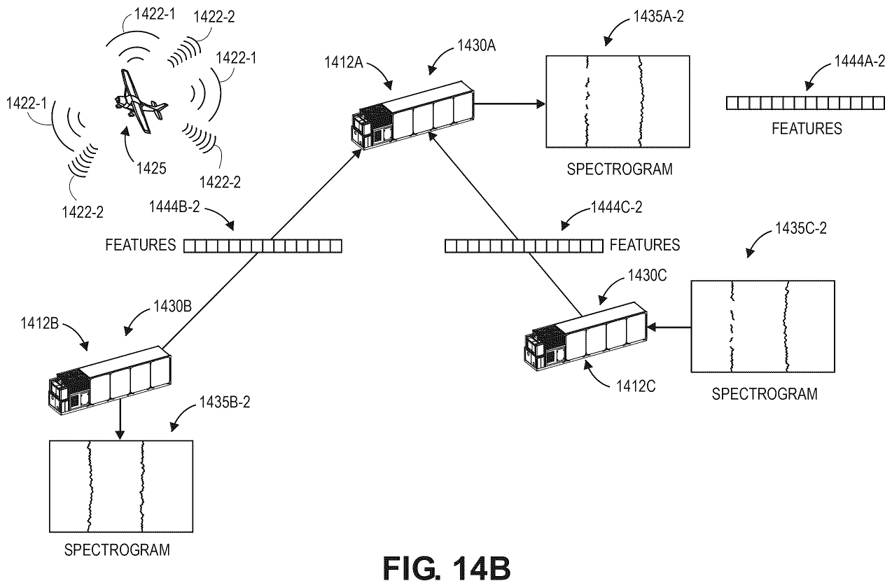

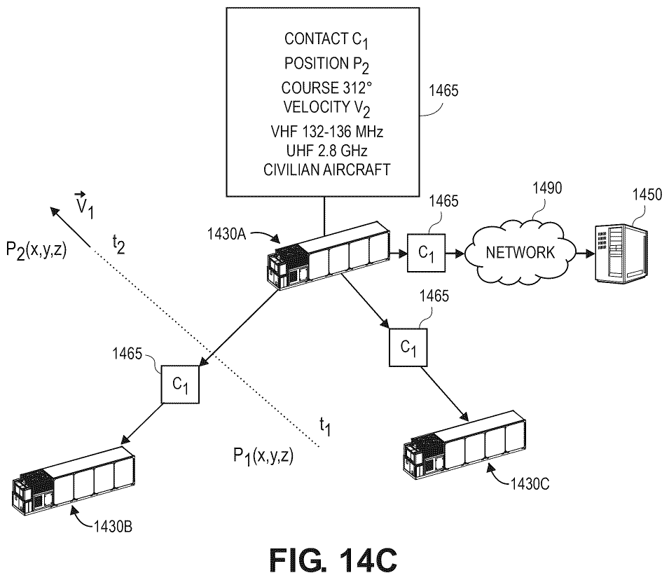

As is discussed above, RF signals (or two-dimensional representations of such signals, or features generated based on such representations) may be processed by an edge computing unit that captured the RF signals. Alternatively, edge computing units or other computer systems may transmit or otherwise exchange information or data regarding RF signals, representations or features between one another, and process such information or data collectively. Referring to FIGS. 14A through 14C, views of aspects of one system in accordance with embodiments of the present disclosure are shown. As is shown in FIGS. 14A and 14B, an aircraft 1425 travels within an airspace in a vicinity of three edge computing units 1430A, 1430B, 1430C. The aircraft 1425 emits a plurality of RF signals 1422-1, 1422-2, which may include communications signals, radar signals, or RF signals of any other type. Additionally, each of the edge computing units 1430A, 1430B, 1430C is outfitted with one or more receivers 1412A, 1412B, 1412C, which may be configured to capture emissions of RF signals at any frequency or wavelength and any intensity or strength. In some implementations, the receivers 1412A, 1412B, 1412C may include one or more all-digital components that are specifically configured for advanced RF signal processing and analysis.

As is further shown in FIGS. 14A and 14B, each of the edge computing units 1430A, 1430B, 1430C is further configured to generate spectrograms or other two-dimensional representations following the capture of the RF signals 1422-1, 1422-2 emitted by the aircraft 1425, and to generate sets of features from such spectrograms or other representations. For example, as is shown in FIG. 14A, each of the edge computing units 1430A, 1430B, 1430C may generate spectrograms 1435A-1, 1435B-1, 1435C-1 by transforming data regarding the RF signals 1422-1, 1422-2 that were captured with the aircraft 1425 in a first position from a time domain to a frequency domain, e.g., by a Fourier Transform process, and plotting data regarding frequencies over time, with signal powers or intensities of the RF signals 1422-1, 1422-2 shown according to a gradient. Each of the edge computing units 1430A, 1430B, 1430C may also generate sets of features 1444A-1, 1444B-1, 1444C-1 from the spectrograms 1435A-1, 1435B-1, 1435C-1. Additionally, the edge computing units 1430A, 1430B, 1430C may exchange data regarding RF signals, spectrograms or features between or among one another. For example, as is also shown in FIG. 14A, the edge computing units 1430B, 1430C transmit the sets of features 1444B-1, 1444C-1 generated thereby to the edge computing unit 1430A.

Similarly, as is shown in FIG. 14B, each of the edge computing units 1430A, 1430B, 1430C may generate spectrograms 1435A-2, 1435B-2, 1435C-2 from data regarding the RF signals 1422-1, 1422-2 that were captured with the aircraft 1425 in a second position, and also generate sets of features 1444A-2, 1444B-2, 1444C-2 from the spectrograms 1435A-2, 1435B-2, 1435C-2. Additionally, the edge computing units 1430B, 1430C transmit the sets of features 1444B-2, 1444C-2 generated thereby to the edge computing unit 1430A.

As is shown in FIG. 14C, the edge computing unit 1430A processes the sets of features 1444A-1, 1444A-2 that the edge computing unit 1430A generated based on the spectrograms 1435A-1, 1435A-2., as well as the sets of features 1444B-1, 1444B-2 that the edge computing unit 1430A received from the edge computing unit 1430B and the sets of features 1444C-1, 1444C-2 that the edge computing unit 1430A received from the edge computing unit 1430C to determine a set of information 1465 regarding a source of the RF signals 1422-1, 1422-2, viz., the aircraft 1425, and the RF signals 1422-1, 1422-2 themselves.

In particular, the edge computing unit 1430A determines that the sets of features 1444A-1, 1444B-1, 1444C-1 each represent common events including transmissions of the RF signals 1422-1, 1422-2 by the aircraft 1425 at a first time t₁, and that the sets of features 1444A-2, 1444B-2, 1444C-2 each represent common events including transmissions of the RF signals 1422-1, 1422-2 by the aircraft 1425 at a second time t₂. The edge computing unit 1430A then matches the events represented in the respective sets of features 1444A-1, 1444B-1, 1444C-1 and calculates ranges from the respective edge computing units 1430A, 1430B, 1430C to the aircraft 1425 at the first time t₁ to determine coordinates P₁ of the first position of the aircraft 1425 at the first time t₁. Likewise, the edge computing unit 1430A then matches the events represented in the respective sets of features 1444A-2, 1444B-2, 1444C-2 and calculates ranges from the respective edge computing units 1430A, 1430B, 1430C to the aircraft 1425 at the second time t₂ to determine coordinates P₂ of the second position of the aircraft 1425 at the second time t₂. Based on the coordinates P₁ of the first position of the aircraft 1425 at the first time t₁ and the coordinates P₂ of the second position of the aircraft 1425 at the second time t₂, the edge computing unit 1430 may calculate a course defined by the respective positions and a velocity V₁ of the aircraft 1425.

The edge computing unit 1430A also determines frequencies of the respective RF signals 1422-1, 1422-2, and classifies a source of the RF signals 1422-1, 1422-2 as a civilian aircraft. The edge computing unit 1430A may classify the aircraft 1425 based on any information or data determined from the respective sets of features 1444A-1, 1444B-1, 1444C-1 and the respective sets of features 1444A-2, 1444B-2, 1444C-2, such as frequencies or intensities of the respective RF signals 1422-1, 1422-2, as well as the coordinates P₁, P₂ of the positions of the aircraft 1425 at the first time t₁ or the second time t₂, the course, the velocity V₁, or any other relevant attributes of the events that included the transmissions of the RF signals 1422-1, 1422-2.

The edge computing unit 1430A further transmits the set of information 1465 to the edge computing units 1430B, 1430C, as well as any number of external computer devices or systems 1450, which may further process the set of information 1465 in any other manner.

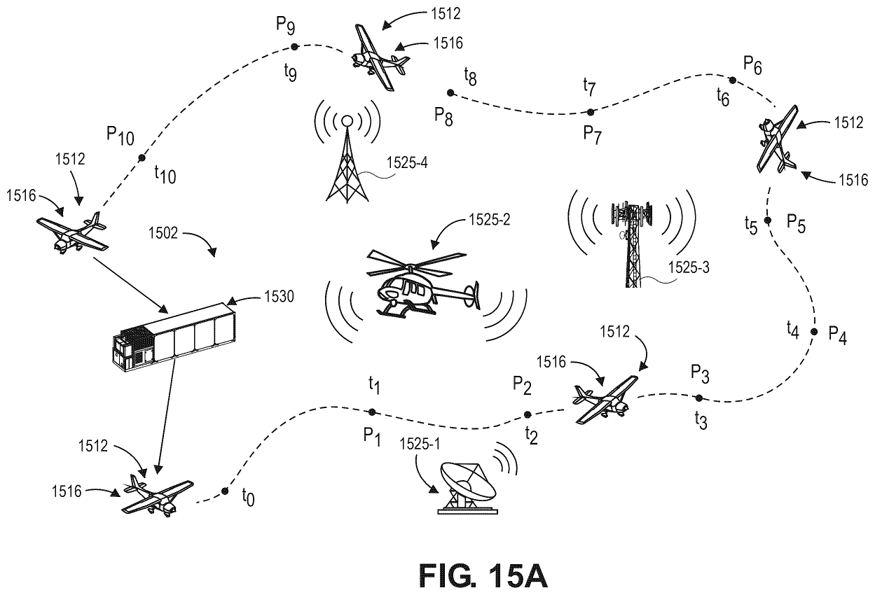

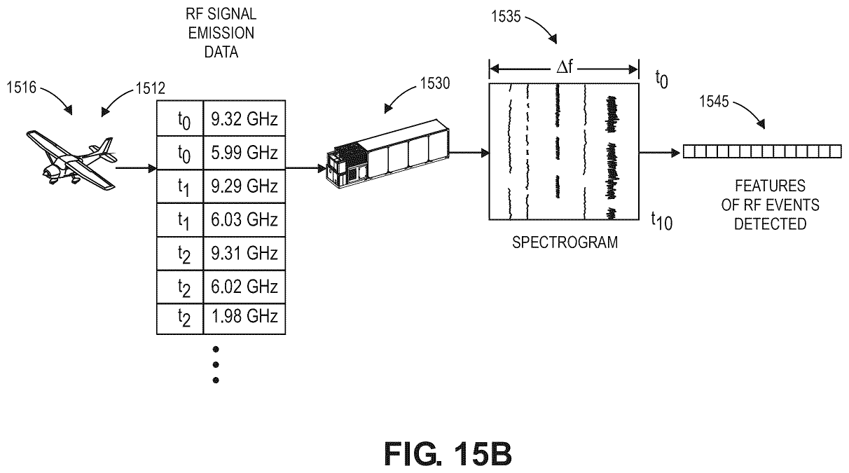

Additionally, vehicles or other assets that capture RF signals within an environment may transmit information or data regarding such signals to an edge computing unit or another external computer device or system for processing. Referring to FIGS. 15A and 15B, views of aspects of one system in accordance with implementations of the present disclosure are shown.

As is shown in FIG. 15A, an aircraft 1516 (or another asset) including one or more receivers 1512 thereon travels on a route including a plurality of positions P₁ through P₁₀ over or around a local site 1502 that includes an edge computing unit 1530. The aircraft 1516 travels over or near a plurality of sources of RF signals, including a communications system 1525-1, an airborne helicopter 1525-2, a cellular communications tower 1525-3 and a radio communications tower 1525-4, and passes through the positions P₁ through P₁₀ during a period of time between a time t₀ and a time t₁₀.

As is shown in FIG. 15B, after raveling along the route including the positions P₁ through P₁₀, the aircraft 1516 transmits a set of data regarding RF signals captured by the receiver 1512 between the time t₀ and the time t₁₀, to the edge computing unit 1530. The edge computing unit 1530 further processes the set of data to generate a spectrogram 1535 or another two-dimensional representation of the RF signals captured by the receiver 1512. The spectrogram 1535 may be encoded with information or data regarding a range Δf of frequencies, as well as any other information or data regarding the aircraft 1516 or the positions P₁ through P₁₀, or a range of times between the time t₀ and the time t₁₀, and a set of features 1545 may be derived from the spectrogram 1535 as encoded. Subsequently, the set of features 1545 may be utilized for any purpose in accordance with implementations of the present disclosure.

Although some embodiments of the present disclosure show the use of edge computing units in support of operations in one or more specific applications or functions, those of ordinary skill in the pertinent arts will realize that the systems and methods of the present disclosure are not so limited. Rather, the systems and methods of the present disclosure may be utilized by any type or form of computing system, in support of any operations in any type of application or function.

It should be understood that, unless otherwise explicitly or implicitly indicated herein, any of the features, characteristics, alternatives or modifications described regarding a particular embodiment herein may also be applied, used, or incorporated with any other embodiment described herein, and that the drawings and detailed description of the present disclosure are intended to cover all modifications, equivalents and alternatives to the various embodiments as defined by the appended claims. Moreover, with respect to the one or more methods or processes of the present disclosure described herein, orders in which such methods or processes are presented are not intended to be construed as any limitation on the claimed inventions, and any number of the method or process steps or boxes described herein can be combined in any order and/or in parallel to implement the methods or processes described herein. Additionally, it should be appreciated that the detailed description is set forth with reference to the accompanying drawings, which are not drawn to scale. In the drawings, the use of the same or similar reference numbers in different figures may indicate the same or similar items or features.

Conditional language, such as, among others, “can,” “could,” “might,” or “may,” unless specifically stated otherwise, or otherwise understood within the context as used, is generally intended to convey in a permissive manner that certain embodiments could include, or have the potential to include, but do not mandate or require, certain features, elements and/or steps. In a similar manner, terms such as “include,” “including” and “includes” are generally intended to mean “including, but not limited to.” Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

The elements of a method, process, or algorithm described in connection with the embodiments disclosed herein can be embodied directly in hardware, in a software module stored in one or more memory devices and executed by one or more processors, or in a combination of the two. A software module can reside in RAM, flash memory, ROM, EPROM, EEPROM, registers, a hard disk, a removable disk, a CD-ROM, a DVD-ROM or any other form of non-transitory computer-readable storage medium, media, or physical computer storage known in the art. An example storage medium can be coupled to the processor such that the processor can read information from, and write information to, the storage medium. In the alternative, a storage medium can be integral to a processor, and can be volatile or non-volatile. The processor and the storage medium can reside in an ASIC. The ASIC can reside in a user terminal. In the alternative, the processor and the storage medium can reside as discrete components in a user terminal.

Disjunctive language such as the phrase “at least one of X, Y, or Z,” or “at least one of X, Y and Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

Language of degree used herein, such as the terms “about,” “approximately,” “generally,” “nearly” or “substantially” as used herein, represent a value, amount, or characteristic close to the stated value, amount, or characteristic that still performs a desired function or achieves a desired result. For example, the terms “about,” “approximately,” “generally,” “nearly” or “substantially” may refer to an amount that is within less than 10% of, within less than 5% of, within less than 1% of, within less than 0.1% of, and within less than 0.01% of the stated amount.

Although the invention has been described and illustrated with respect to illustrative embodiments thereof, the foregoing and various other additions and omissions may be made therein and thereto without departing from the spirit and scope of the present disclosure.

What is claimed is:

1. An edge computing unit comprising:
a signal receiver;
at least one server rack;
at least one power unit;
at least one environmental control system; and
at least one isolation system,
wherein the at least one server rack is programmed with one or more sets of instructions that, when executed by the at least one server rack, cause the edge computing unit to perform operations comprising:
capturing a first plurality of RF signals by the signal receiver over a first period of time;
transforming first data from a time domain to a frequency domain, wherein the first data represents the first plurality of RF signals;
generating a first spectrogram representative of the first plurality of RF signals based at least in part on the transformed first data;
extracting a first set of features from the first spectrogram;
encoding the first set of features with a frequency range associated with the first data;
identifying a plurality of sets of features, wherein each one of the plurality of sets of features is associated with one of a plurality of RF events, and wherein each one of the plurality of RF events comprises at least one transmission of at least one RF signal;
generating, by a spectrum encoder of a transformer model, at least a first embedding based at least in part on the first set of features and the plurality of sets of features, wherein generating at least the first embedding comprises performing attention on the first set of features and each one of the plurality of sets of features;
receiving, from a computer device, a query for information regarding at least one of the first plurality of RF signals or the first period of time;
generating, by a text encoder, at least a second embedding based at least in part on the query for information;
identifying at least a third embedding, wherein the third embedding was generated by encoding at least one document associated with one of RF signals or sources of RF signals;
generating, by a spectrum decoder of the transformer model, at least one response to the query for information, wherein generating the at least one response comprises performing attention on the first embedding, the second embedding, and the third embedding, and wherein the at least one response comprises a set of words regarding the at least one of the first plurality of RF signals or a source of the at least one of the first plurality of RF signals;
transmitting second data representing the set of words to the computer device; and
causing the computer device to display or play aloud the set of words based at least in part on the second data.

2. The edge computing unit of claim 1, wherein the signal receiver comprises:
at least one superconductor chip, wherein the at least one superconductor chip is cooled to below twenty degrees Kelvin; and
at least one post-processing module comprising a field programmable gate array.

3. The edge computing unit of claim 1, wherein the set of words indicates that at least one of the first plurality of RF signals is associated with one of the plurality of RF events.

4. A method comprising:
capturing first data regarding at least a first transmission of RF signals over a period of time, wherein the first data is captured in the time domain by a first receiver;
transforming the first data regarding the first transmission of the RF signals to a frequency domain;
generating at least a first two-dimensional representation based at least in part on the first data transformed to the frequency domain;
extracting at least a first set of features from the first two-dimensional representation;
encoding at least the first set of features with second data representing at least one range of frequencies associated with the first data;
identifying a first plurality of sets of features, wherein each one of the first plurality of sets of features was extracted from one of a plurality of two-dimensional representations generated based at least in part on data regarding RF signals associated with one of a plurality of RF events transformed to the frequency domain;
generating at least a first embedding based at least in part on the first set of features encoded with the second data and at least some of the first plurality of sets of features; and
identifying at least one attribute of the first transmission of the RF signals based at least in part on the first embedding.

5. The method of claim 4, wherein the first receiver is a component of an edge computing unit comprising a containerized system having:
at least one server rack;
at least one power unit;
at least one environmental control system; and
at least one isolation system.

6. The method of claim 4, wherein the first receiver comprises:
at least one superconductor chip, wherein the at least one superconductor chip is cooled to below twenty degrees Kelvin; and
at least one post-processing module comprising a field programmable gate array, and
wherein the edge computing unit further comprises one or more rack-mounted redundant arrays of independent disks.

7. The method of claim 4, wherein generating at least the first two-dimensional representation based at least in part on the first data comprises:
partitioning the first two-dimensional representation into a plurality of tiles, wherein each one of the plurality of tiles is a portion of the first two-dimensional representation,
wherein extracting at least the first set of features from the first two-dimensional representation comprises:
extracting a second plurality of sets of features from the plurality of tiles, wherein each one of the second plurality of sets of features is extracted from one of the plurality of tiles, and
wherein encoding at least the first set of features with the second data comprises:
encoding each one of the second plurality of sets of features with data representing a range of features corresponding to the one of the plurality of tiles from which the one of the second plurality of features was extracted.

8. The method of claim 4, wherein the at least one attribute of the first transmission of the RF signals comprises:
a frequency associated with the first transmission of the RF signals;
an identifier of a source of the first transmission of the RF signals;
an identifier of an entity associated with the source of the first transmission of the RF signals;
an intensity of the first transmission of the RF signals;
a location of the first transmission of the RF signals; or
a purpose of the first transmission of the RF signals.

9. The method of claim 8, wherein the at least one attribute of the first transmission of the RF signals is one of a frequency associated with the first transmission of the RF signals, an intensity of the first transmission of the RF signals, an identifier of a source of the first transmission of the RF signals, or a location of the first transmission of the RF signals, and
wherein the method further comprises:
classifying the first transmission of the RF signals as at least a portion of one of the plurality of RF events based at least in part on the at least one of the frequency associated with the first transmission of the RF signals, the intensity of the first transmission of the RF signals, the source of the first transmission of the RF signals or the location of the first transmission of the RF signals; and
storing an indication that the first transmission of the RF signals is at least a portion of the one of the plurality of RF events in at least one data store.

10. The method of claim 8, wherein the at least one attribute of the first transmission of the RF signals is one of a frequency associated with the first transmission of the RF signals, an intensity of the first transmission of the RF signals, an identifier of a source of the first transmission of the RF signals, or a location of the first transmission of the RF signals, and wherein the method further comprises:
determining that the first transmission of the RF signals is not one of the plurality of RF events based at least in part on the at least one of the frequency associated with the first transmission of the RF signals, the intensity of the first transmission of the RF signals, the source of the first transmission of the RF signals or the location of the first transmission of the RF signals; and
storing an indication that the first transmission of the RF signals is not one of the plurality of RF events in at least one data store.

11. The method of claim 8, further comprising:
receiving at least a second embedding over one or more networks, wherein the second embedding is generated based at least in part on a second set of features extracted from a second two-dimensional representation generated based at least in part on third data regarding the first transmission of RF signals transformed to the frequency domain and at least some of a second plurality of sets of features extracted from one of the plurality of two-dimensional representations;
determining that each of the first embedding and the second embedding was generated based at least in part on the first transmission of RF signals at a common time; and
determining, based at least in part on the first embedding and the second embedding, the at least one attribute of the first transmission of the RF signals, wherein the at least one attribute is a location of the source at the common time.

12. The method of claim 4, wherein the first embedding is generated by a spectrum encoder of a transformer model,
wherein the spectrum encoder comprises:
a self-attention module comprising a multi-head attention feature, at least one normalization layer, and at least one feedforward network, wherein the self-attention module is configured to perform attention on at least the first set of features encoded with the second data; and
a multi-modal attention module configured to perform attention on at least the attention-refined first set of features encoded with the second data and each of the first plurality of sets of features,
wherein the first embedding is generated based at least in part on an output of the multi-modal attention module.

13. The method of claim 4, wherein identifying the at least one attribute of the first transmission of the RF signals based at least in part on the first embedding comprises:
receiving a query for information;
generating at least a second set of features based at least in part on the query for information;
encoding the second set of features with third data representing at least one range of frequencies associated with the query for information;
identifying a second plurality of sets of features, wherein each one of the second plurality of sets of features was generated based on semantic information regarding RF signals or sources of RF signals; and
decoding the first embedding based at least in part on the second set of features and the second plurality of sets of features to generate a response to the query for information,
wherein the response to the query for information identifies the at least one attribute.

14. The method of claim 13, wherein the first embedding is decoded by a spectrum decoder of a transformer model,
wherein the spectrum decoder comprises:
a self-attention module comprising a multi-head attention feature, at least one normalization layer, and at least one feedforward network, wherein the self-attention module is configured to perform attention on at least the second set of features encoded with the third data; and
a multi-modal attention module configured to perform attention on at least the attention-refined second set of features encoded with the third data, the first embedding, and each of the second plurality of sets of features,
wherein the response to the query for information is generated based at least in part on an output of the multi-modal attention module.

15. The method of claim 13, wherein the semantic information describes at least one of:
a frequency of an RF signal transmitted prior to the period of time;
an intensity of the RF signal;
a location of a transmission of the RF signal; or
an identifier of a source of the RF signal, and
wherein each one of the second plurality of sets of features was generated by providing the semantic information to a text encoder.

16. The method of claim 4, wherein the first two-dimensional representation is a first spectrogram representing at least the first transmission of RF signals, and
wherein each one of the plurality of two-dimensional representations is a spectrogram generated based at least in part on the data regarding the RF signals associated with the one of the plurality of RF events transformed to the frequency domain.

17. An edge computing unit comprising:
a signal receiver; and
at least one server rack comprising at least one processor unit and at least one data store,
wherein the at least one server rack is programmed with one or more sets of instructions that, when executed, cause the edge computing unit to perform operations comprising:
receiving a query of information from a first computer system over one or more networks;
transforming first data representing a plurality of RF signals captured by the signal receiver to a frequency domain;
generating a first spectrogram based at least in part on the transformed first data;
extracting a first set of features from the first spectrogram;
identifying second data representing a plurality of RF events, wherein each one of the plurality of RF events includes a transmission of at least one RF signal;
extracting a first plurality of sets of features from the second data, wherein each one of the first plurality of sets of features represents one of the plurality of RF events;
executing a spectrum encoder to generate a first plurality of embeddings, wherein each one of the first plurality of embeddings is generated based at least in part on the first set of features and one of the first plurality of sets of features;
generating at least one embedding based at least in part on the query for information;
identifying a second plurality of embeddings, wherein each one of the second plurality of embeddings represents at least a portion of one of a plurality of resources including semantic information regarding RF signals, sources of RF signals or RF events including transmissions of RF signals;
executing a spectrum decoder to generate a response to the query for information based at least in part on the first plurality of embeddings, the at least one embedding generated based at least in part on the query for information, and the second plurality of embeddings; and
providing a set of words generated based at least in part on the output to one of the first computer system or a second computer system.

18. The edge computing unit of claim 17, wherein extracting the first set of features from the first spectrogram comprises:
partitioning the first spectrogram into a plurality of tiles, wherein each one of the plurality of tiles is a portion of the first spectrogram; and
extracting the first plurality of sets of features from the plurality of tiles, wherein each one of the first plurality of sets of features is extracted from one of the plurality of tiles.

19. The edge computing unit of claim 17, wherein the signal receiver comprises:
at least one superconductor chip, wherein the at least one superconductor chip is cooled to below twenty degrees Kelvin; and
at least one post-processing module comprising a field programmable gate array.

20. The edge computing unit of claim 17, wherein the spectrum encoder comprises:
a first self-attention module comprising a first multi-head attention feature, at least a first normalization layer, and at least a first feedforward network, wherein the first self-attention module is configured to perform attention on at least the first set of features encoded with data regarding a frequency range of the first spectrogram; and
a first multi-modal attention module configured to perform attention on at least the attention-refined first set of features encoded with the data regarding the frequency range of the first spectrogram and each of the first plurality of sets of features, and wherein the spectrum decoder comprises:
a second self-attention module comprising a second multi-head attention feature, at least a second normalization layer, and at least a second feedforward network, wherein the second self-attention module is configured to perform attention on the at least one embedding generated based at least in part on the query for information encoded with the data regarding the frequency range of the first spectrogram; and
a second multi-modal attention module configured to perform attention on at least the attention-refined at least one embedding encoded with the data regarding the frequency range of the first spectrogram, the first plurality of embeddings, and the second plurality of embeddings.
